(19) United States
(12) Patent Application Publication
(10) Pub. No.: US 2025/0359060 A1
(43) Pub. Date: Nov. 20, 2025

(54) MICROELECTRONIC DEVICES INCLUDING ISOLATION STRUCTURES WITH AIR GAPS AND RELATED METHODS

(71) Applicant: Micron Technology, Inc., Boise, ID (US)

(72) Inventors: Darwin A. Clampitt, Wilder, ID (US); John D. Hopkins, Meridian, ID (US); Matthew J. King, Boise, ID (US)

(21) Appl. No.: 19/004,756

(22) Filed: Dec. 30, 2024

Related U.S. Application Data
(60) Provisional application No. 63/627,656, filed on Jan. 31, 2024.

(51) Int. Cl. H10B 43/35; H10B 43/20

(52) U.S. Cl. CPC H10B 43/35; H10B 43/20

(57) ABSTRACT

A microelectronic device comprises a first stack structure and a second stack structure comprising a vertically alternating sequence of first and second conductive structures and first and second insulative structures arranged in first and second tiers. Strings of memory cells vertically extend through the first stack structure, the strings of memory cells individually comprising a channel material vertically extending through the first stack structure. Channel structures extend through the second stack structure and vertically overlie and are electrically coupled to the strings of memory cells. Channel openings contain the channel structures and have a first dimension, and the channel structures surround an insulative material. Third conductive structures vertically overlie the channel structures, and a metal silicide region of the channel structures electrically connects the channel structures and the third conductive structures. Conductive structure openings contain the third conductive structures and have a second dimension larger than the first dimension.

### CROSS-REFERENCE TO RELATED APPLICATION

This application claims the benefit under 35 U.S.C. § 119(e) of U.S. Provisional Patent Application Ser. No. 63/627,656, filed Jan. 31, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices including conductive structures and insulative structures comprising air gaps, and to related methods of forming the microelectronic devices.

### BACKGROUND

A continuing goal of the microelectronics industry has been to increase the memory density (e.g., the number of memory cells per memory die) of memory devices, such as non-volatile memory devices (e.g., “not and” (NAND) logic flash memory devices). One way of increasing memory density in non-volatile memory devices is to utilize vertical memory array (also referred to as a “three-dimensional (3D) memory array”) architectures. A conventional vertical memory array includes vertical memory strings extending through openings in a stack of tiers of conductive structures (e.g., word lines) and dielectric materials at each junction of the vertical memory strings and the conductive structures. Such a configuration permits a greater number of switching devices (e.g., transistors) to be located in a unit of die area (i.e., length and width of active surface consumed) by building the array upwards (e.g., longitudinally, vertically) on a die, as compared to structures with conventional planar (e.g., two-dimensional) arrangements of transistors.

Conventional vertical memory arrays include electrical connections between the conductive structures and access lines (e.g., the word lines) so that memory cells in the vertical memory array can be uniquely selected for writing, reading, or erasing operations. As vertical memory array technology has advanced, additional memory density has been provided by forming vertical memory arrays to include stacks comprising additional tiers of conductive structures and, hence, additional staircase structures and/or additional steps in individual staircase structures associated therewith. As the number of tiers of the conductive structures increases, processing conditions for the formation of the vertical memory strings extending through the stack becomes increasingly complex. In addition, as the thickness of each tier decreases to increase the number of tiers within a given height of the stack, the resistivity of the conductive structures may increase and the conductivity may exhibit a corresponding decrease. However, a reduction in the resistivity of the conductive structures may impact performance of the strings of memory cells.

### BRIEF DESCRIPTION OF THE DRAWINGS

FIG. 1A, FIG. 1B and FIG. 1Ai show various simplified views of pillar structures used in 3D NAND memory devices according to some embodiments.

FIGS. 2A through 2H, 2K, 2M, 2N, 2P through 2X show simplified transverse cross section elevation views of first and second stack structures during fabrication of channel structures and conductive structures above the pillar structures according to several embodiments.

FIGS. 3A through 3X show simplified transverse cross section elevation views of first and second stack structures during fabrication of channel structures and conductive structures above the pillar structures according to several embodiments.

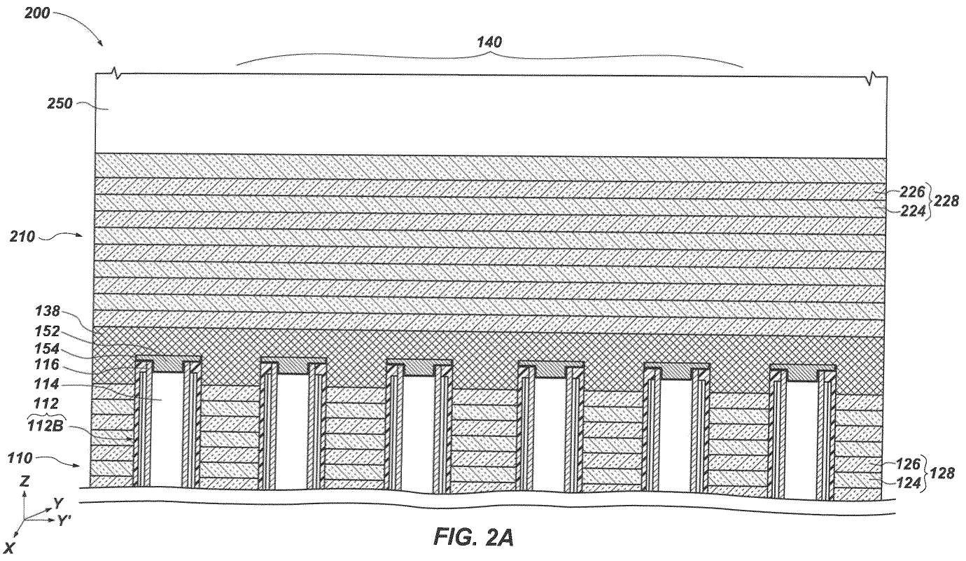

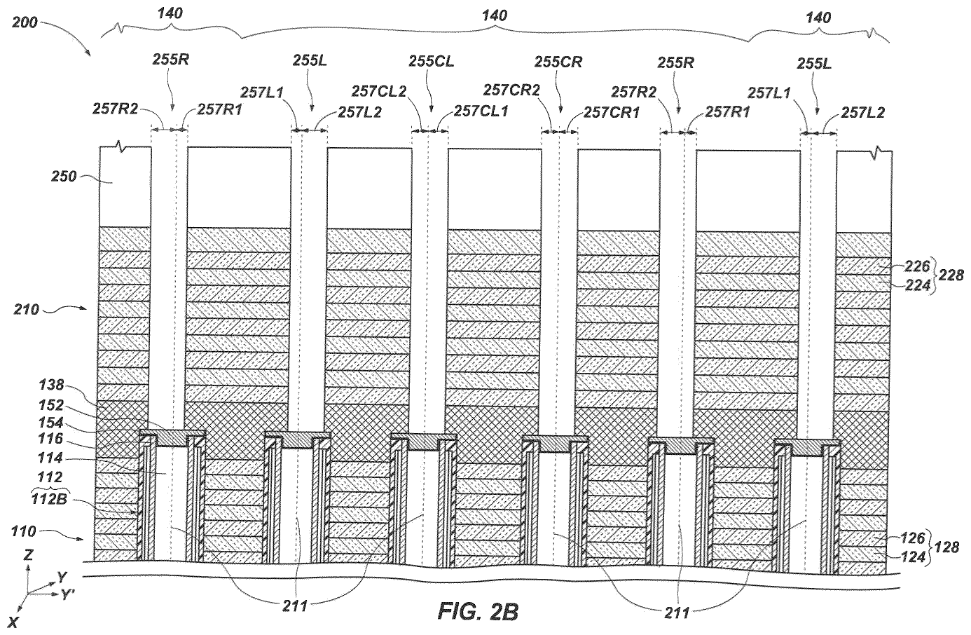

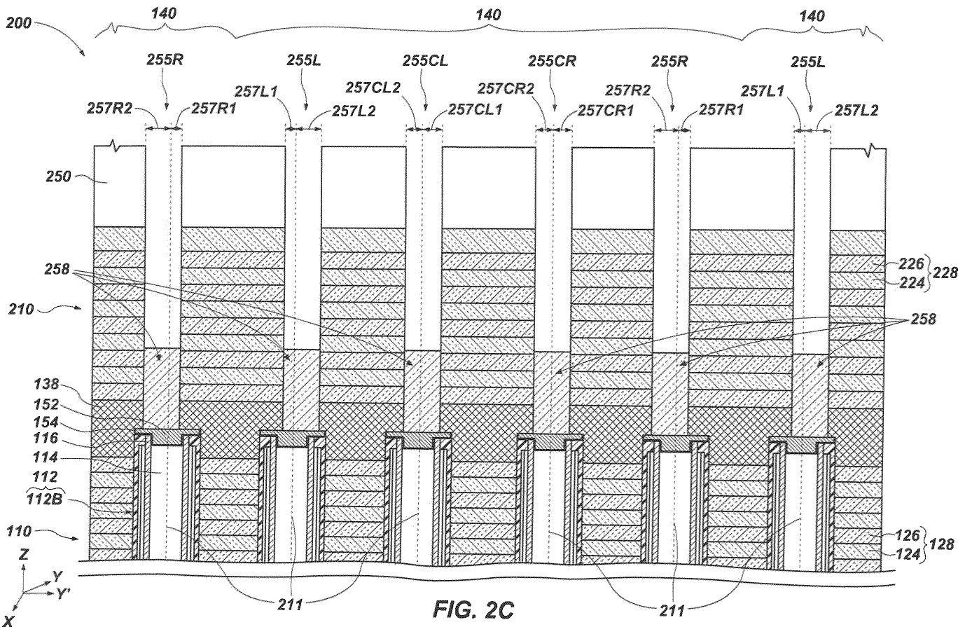

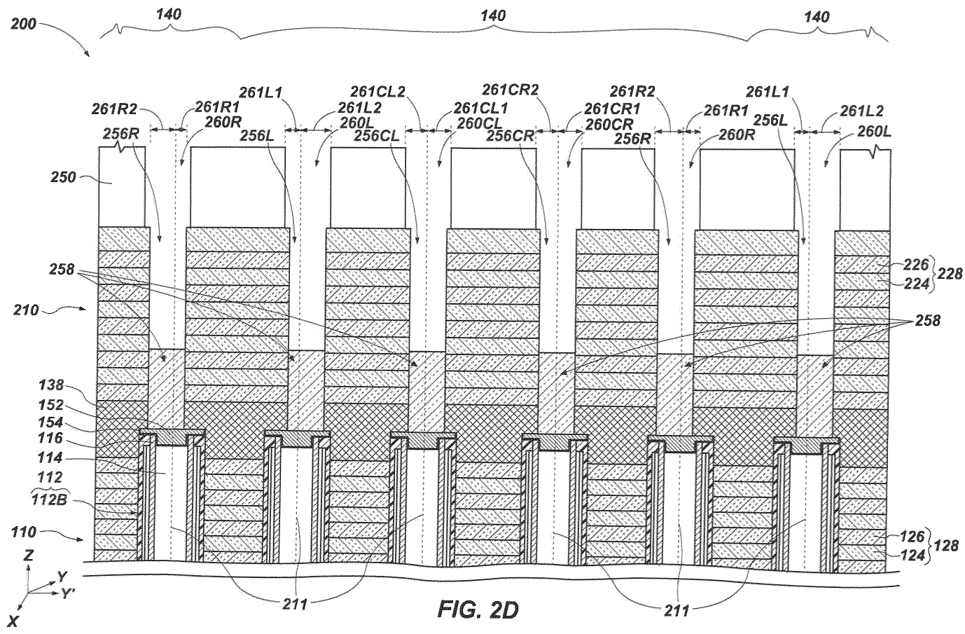

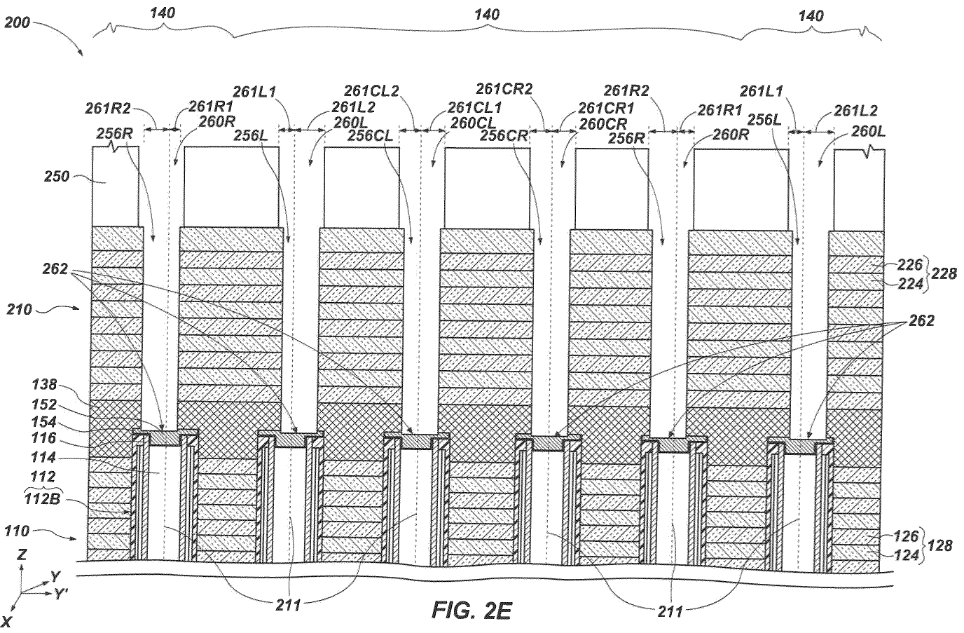

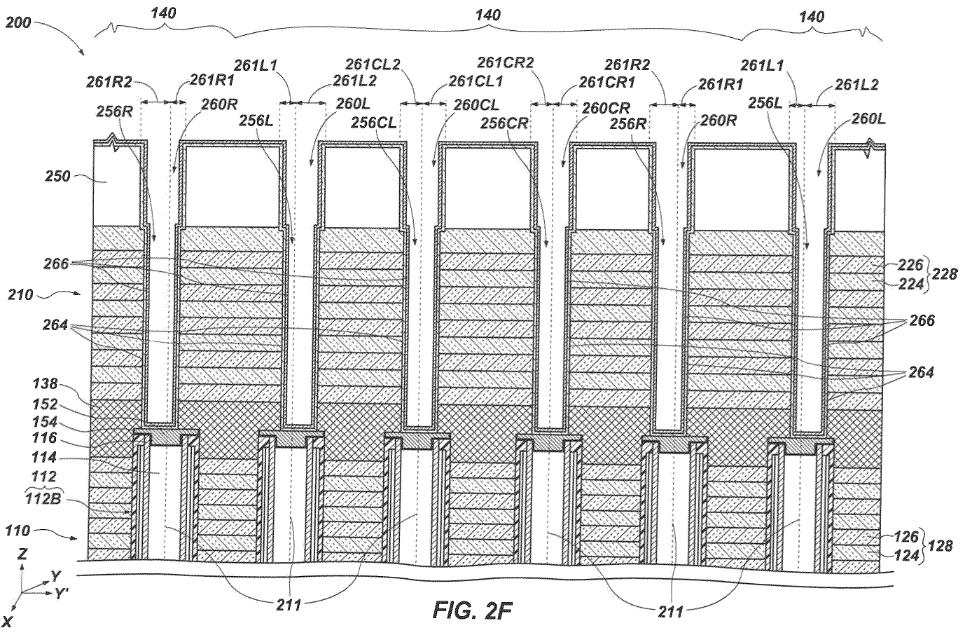

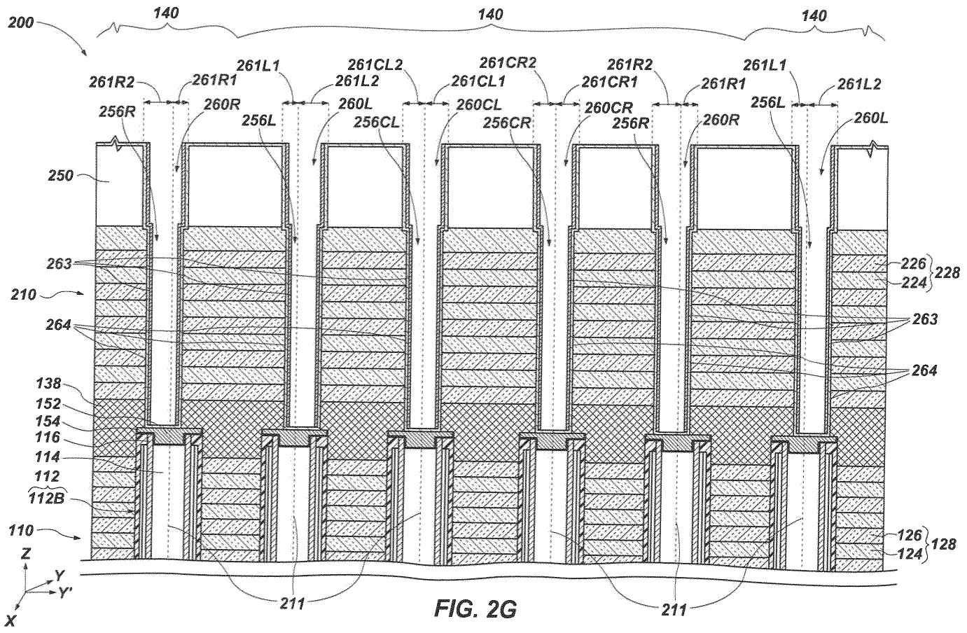

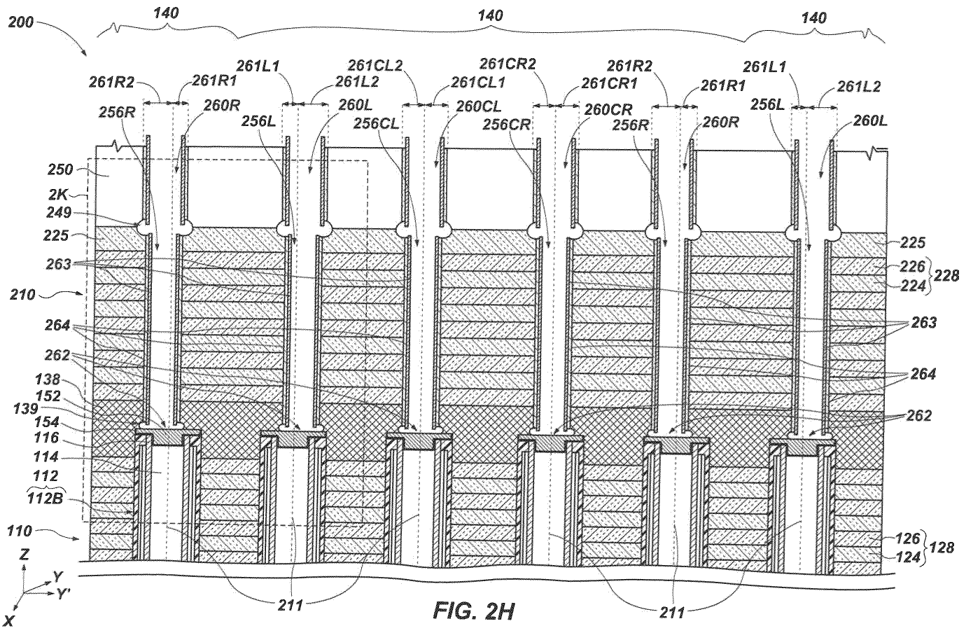

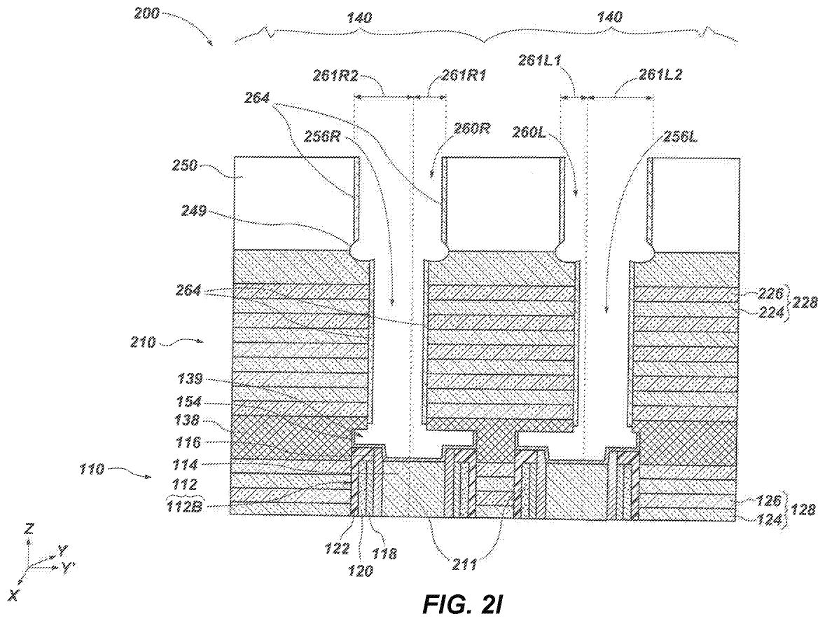

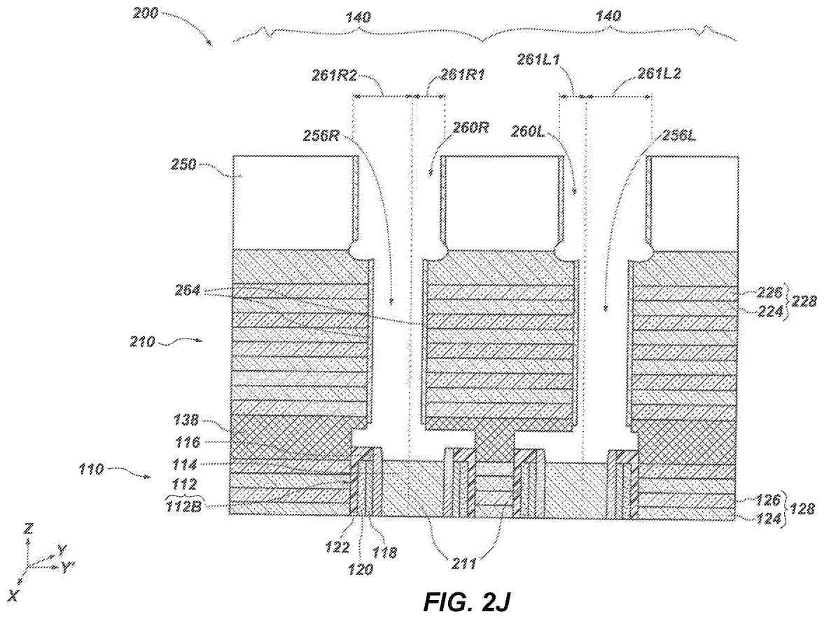

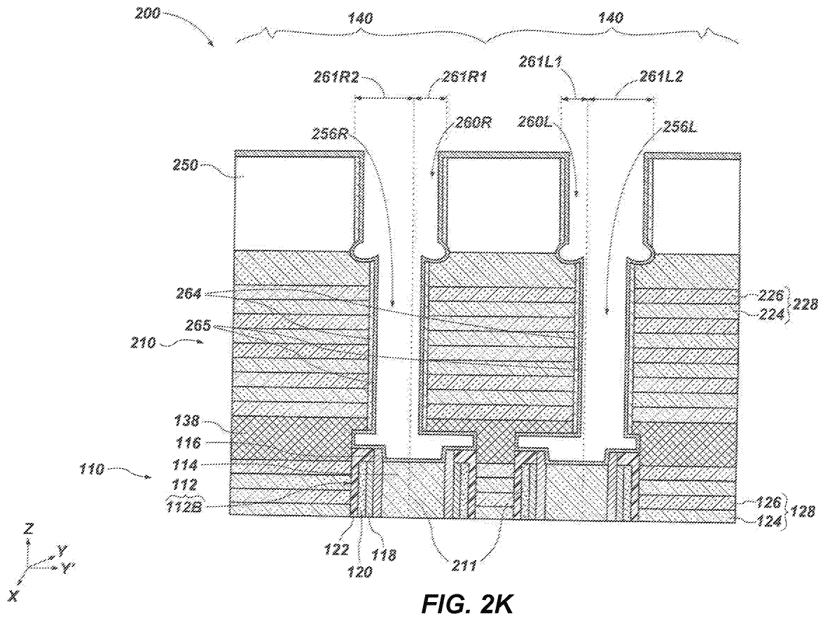

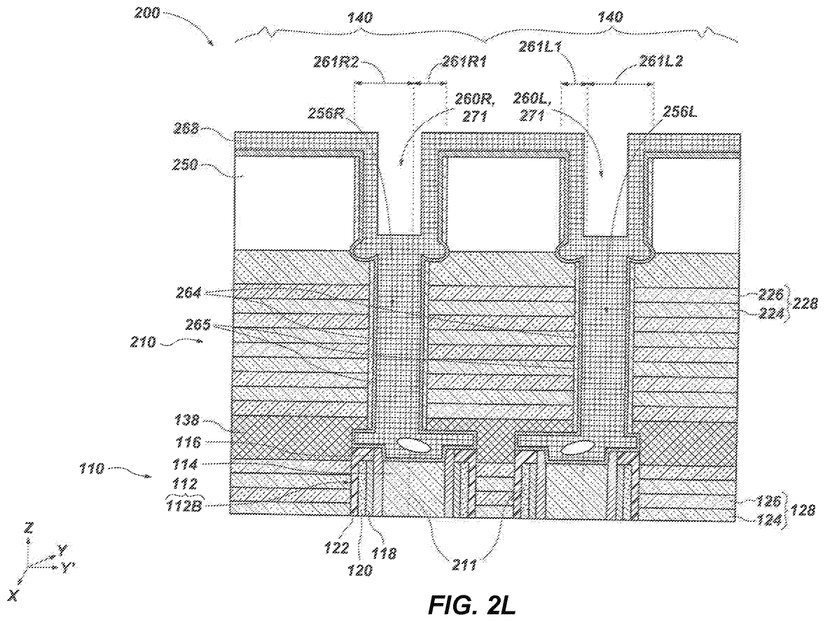

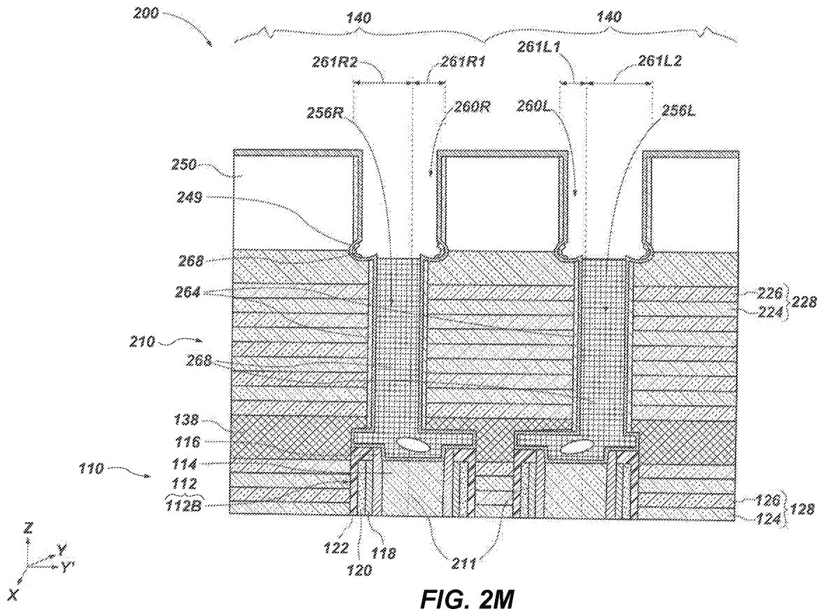

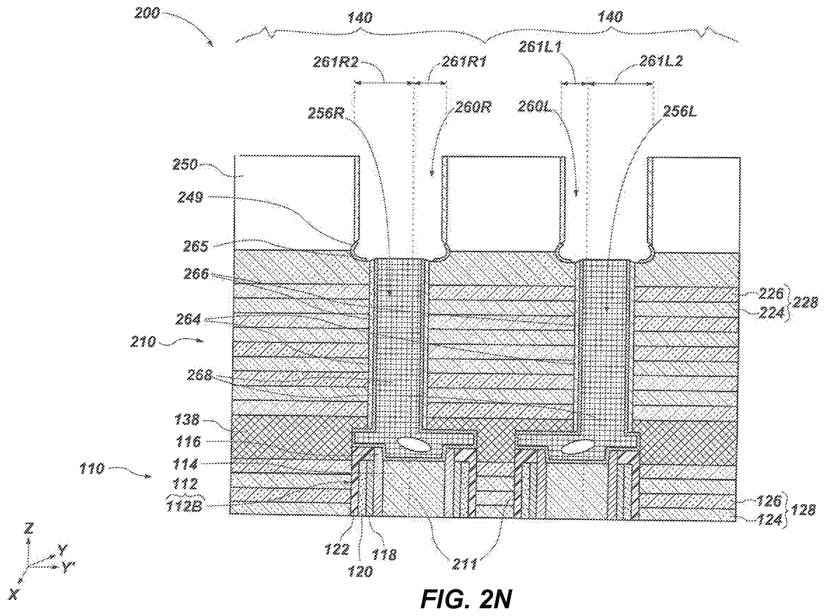

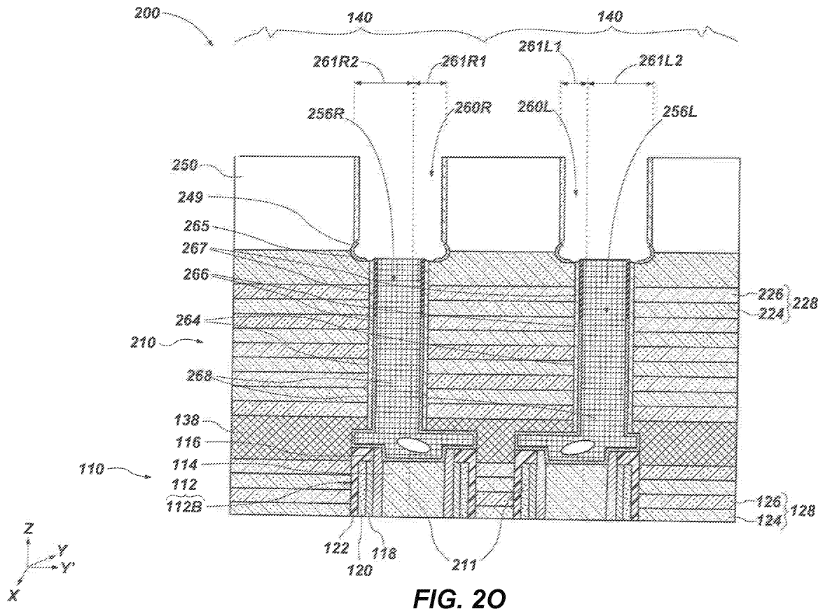

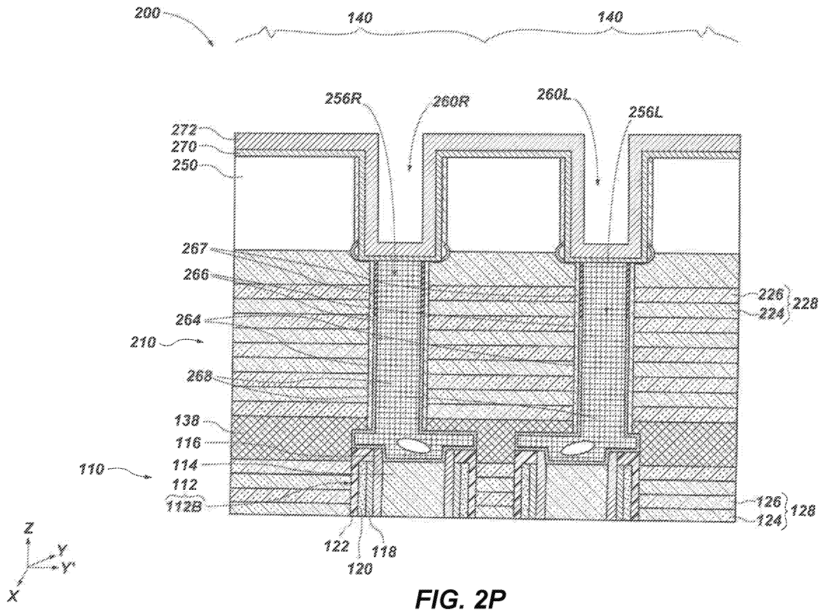

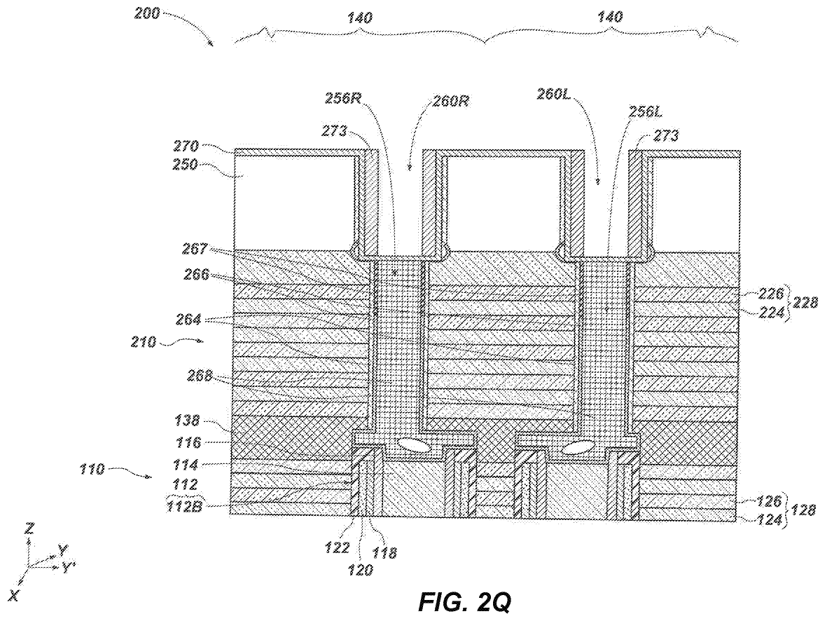

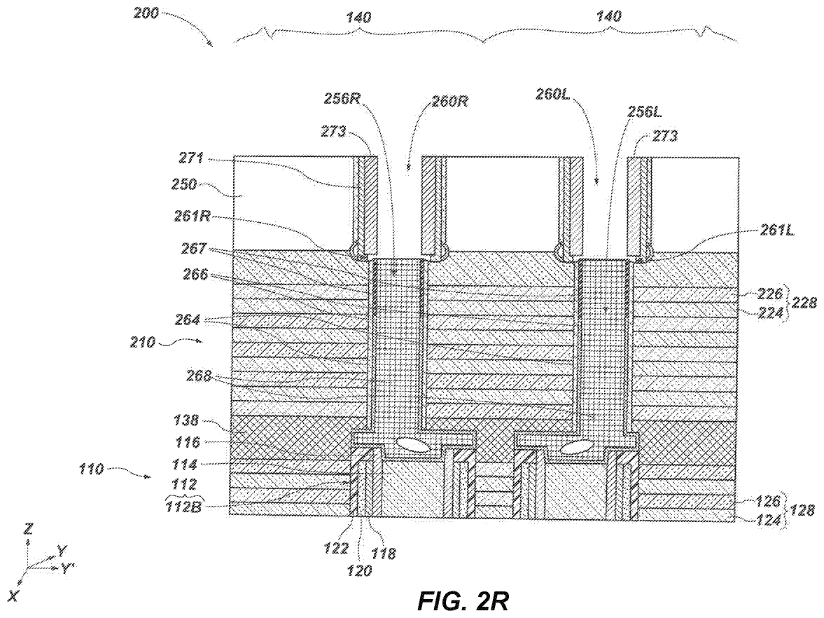

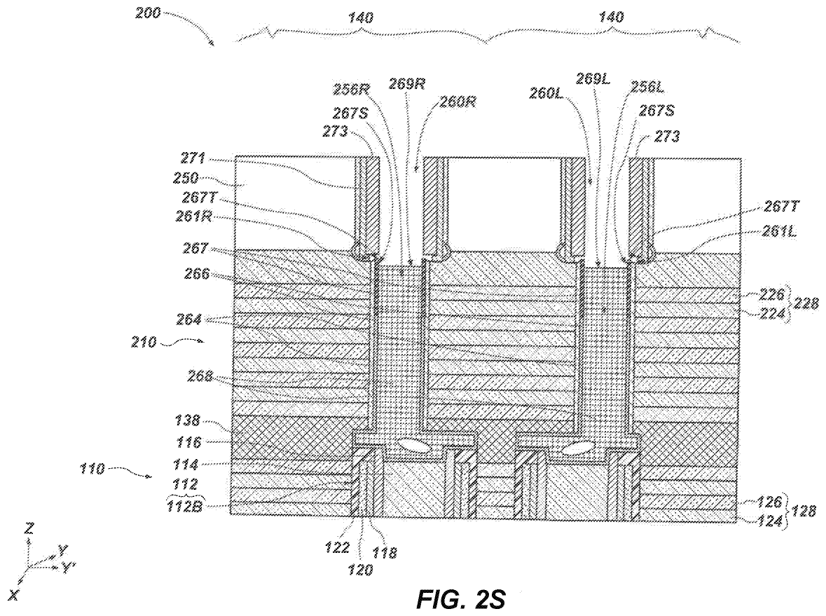

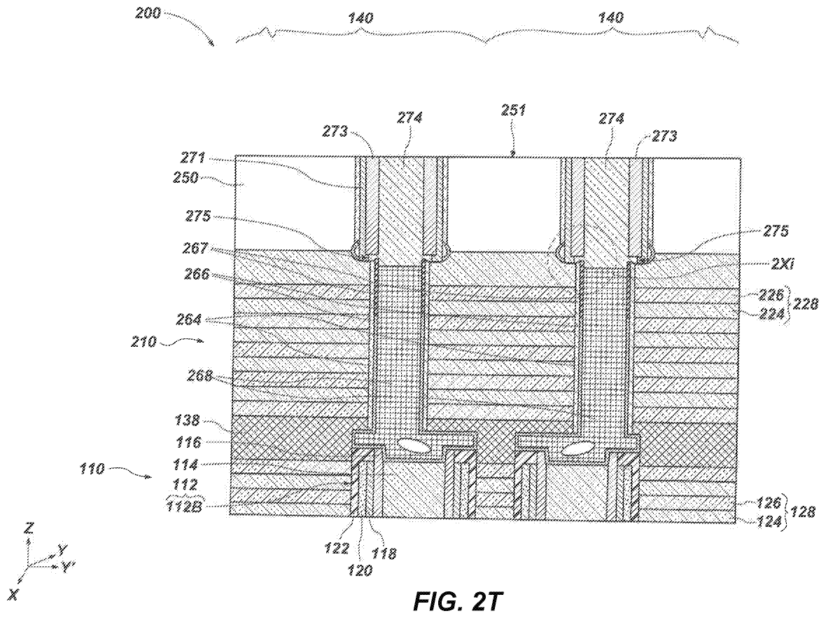

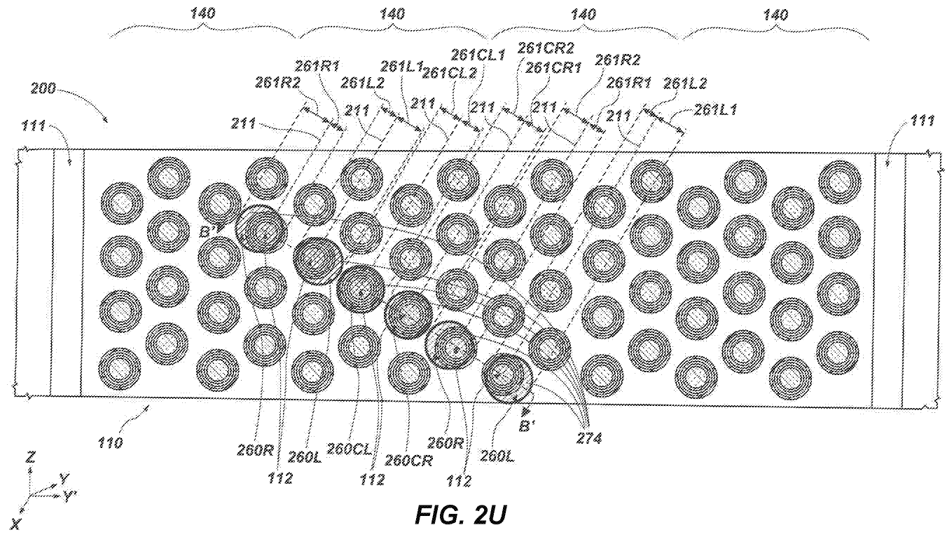

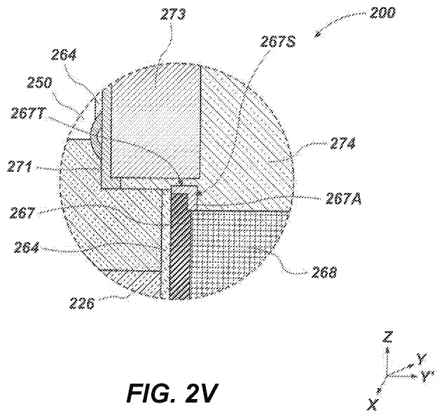

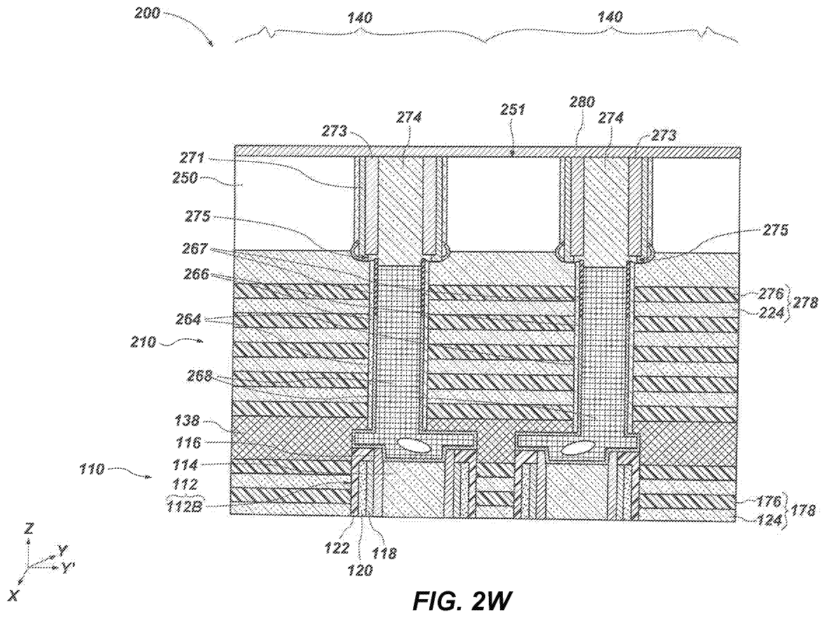

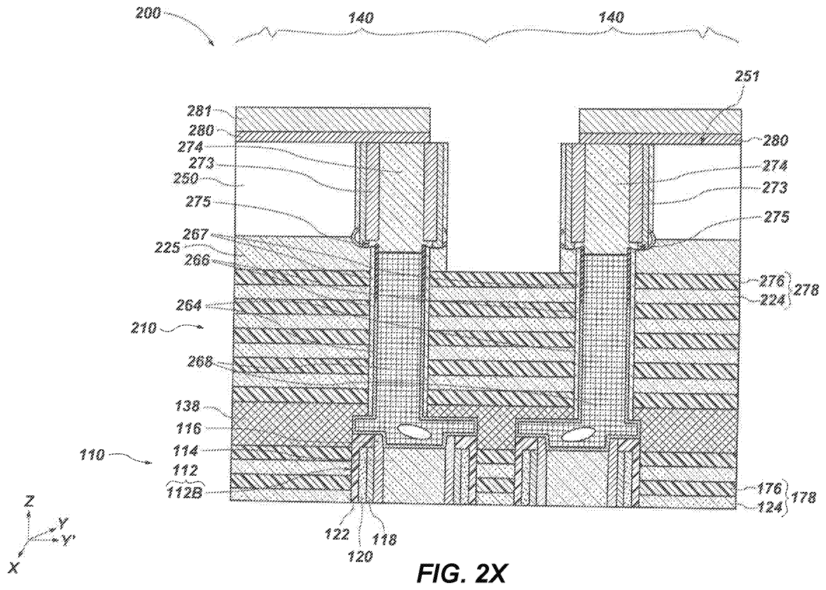

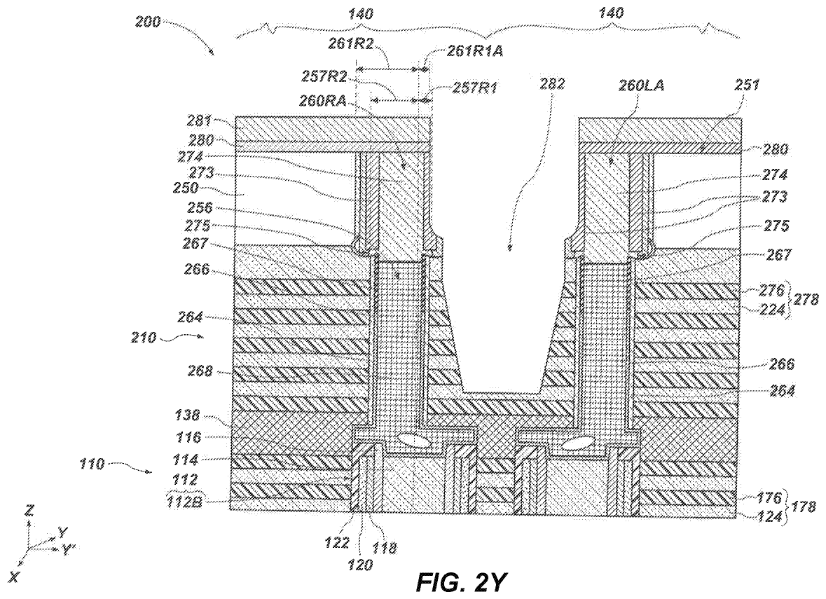

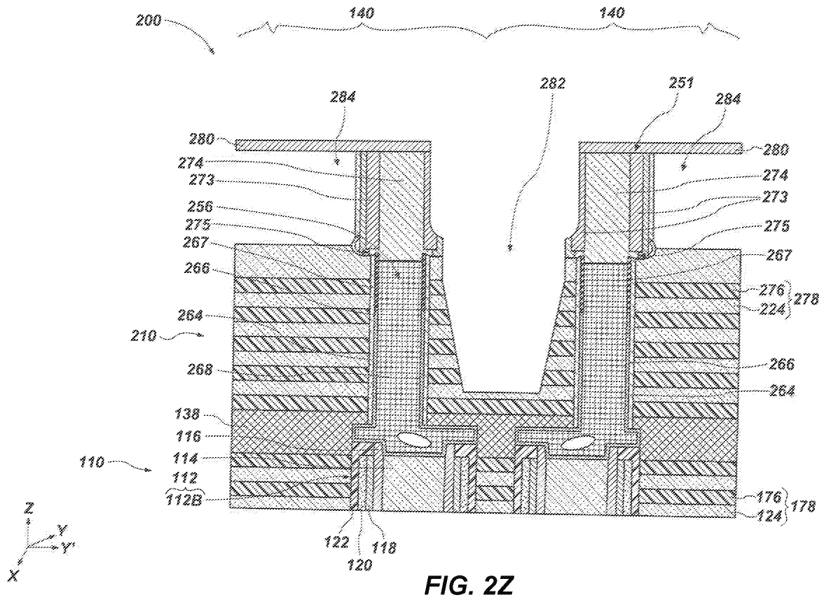

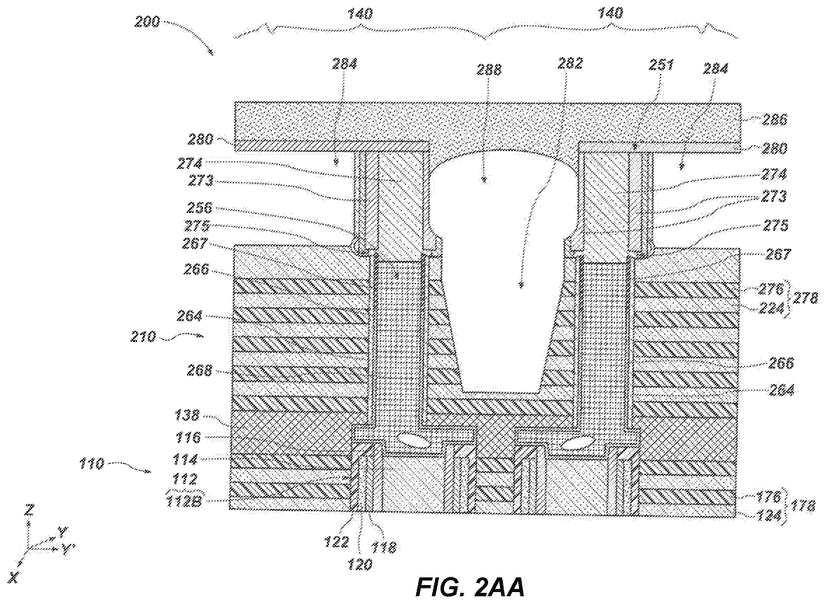

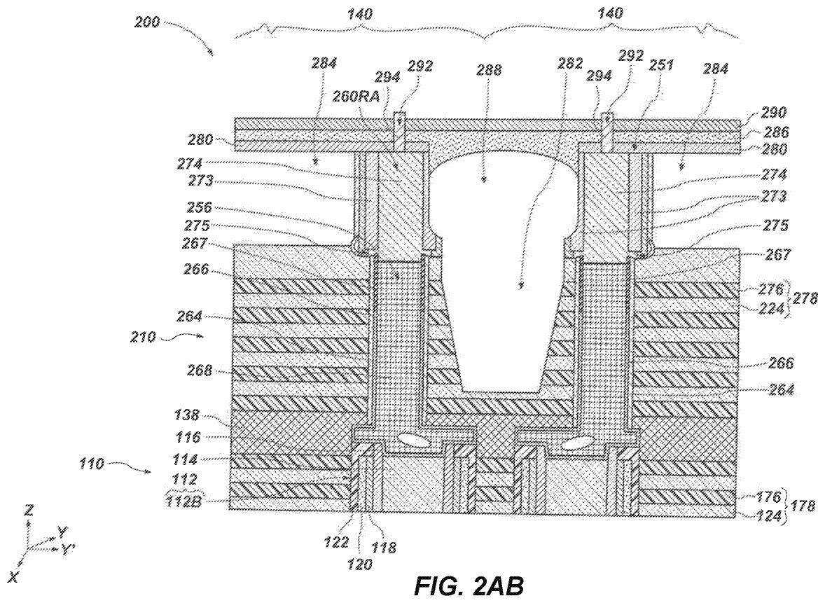

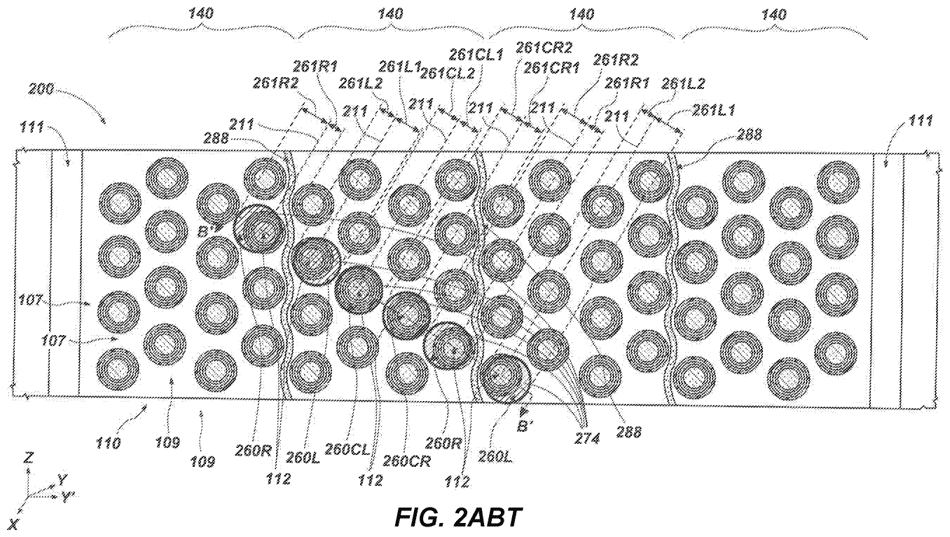

FIG. 2XT and FIG. 2Xi show different simplified views of channel structures and conductive structures according to some embodiments.

FIGS. 2Y through 2AD show simplified transverse cross section elevation views of the channel structures and conductive structures during further fabrication of isolation structures according to several embodiments.

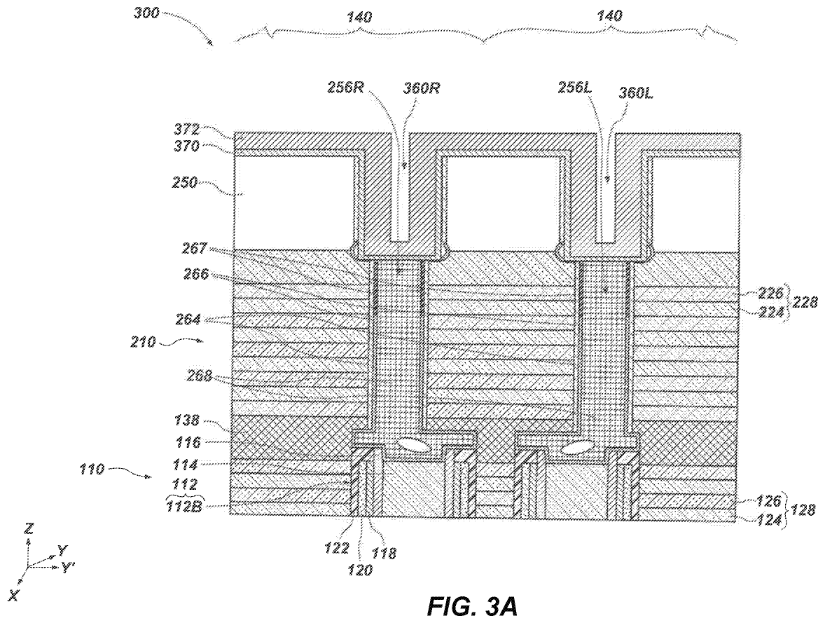

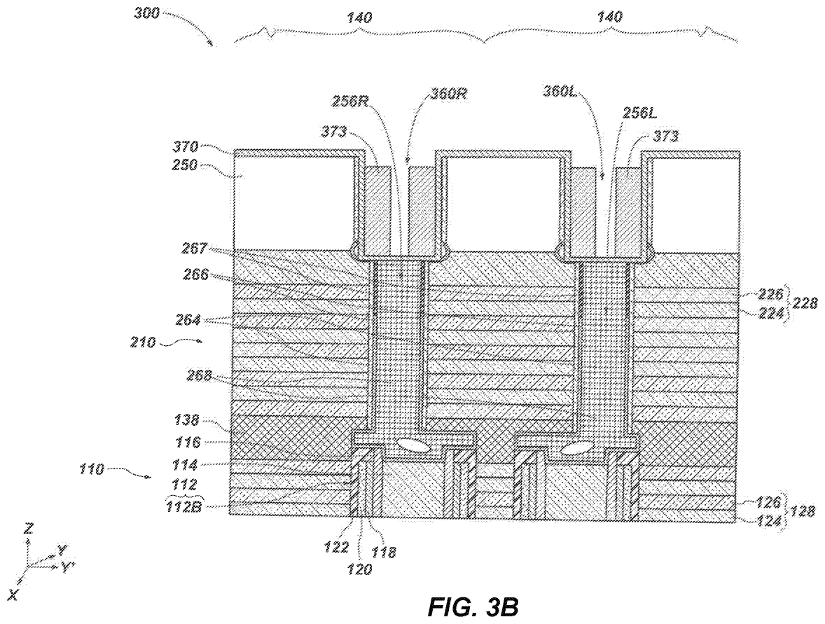

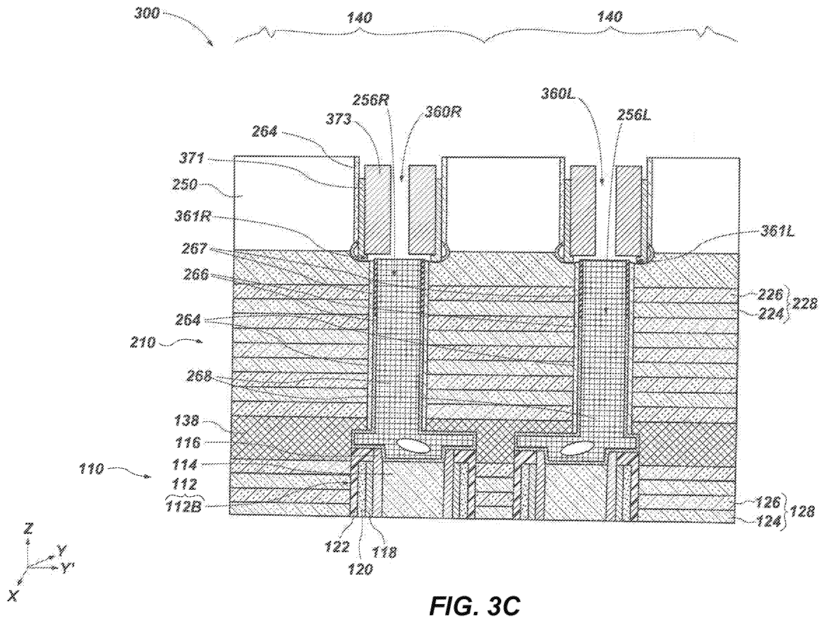

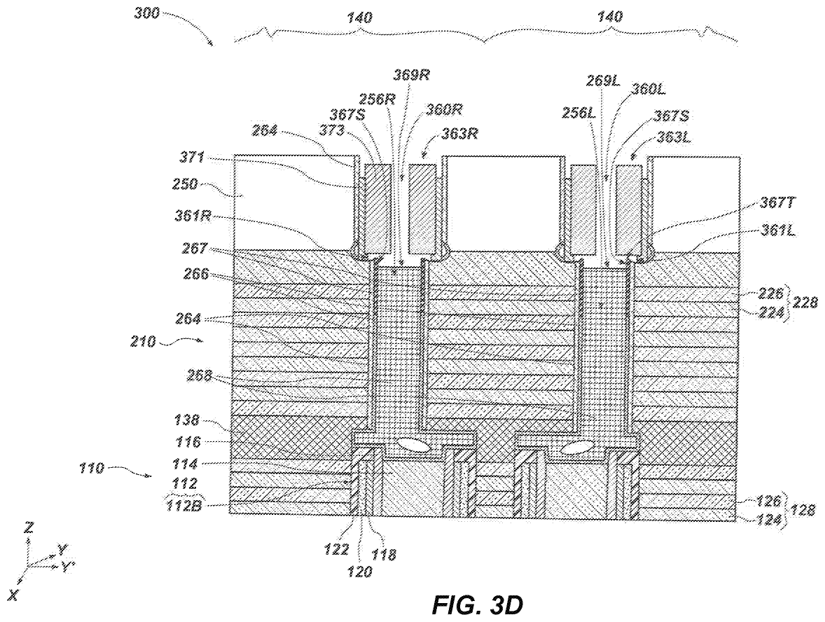

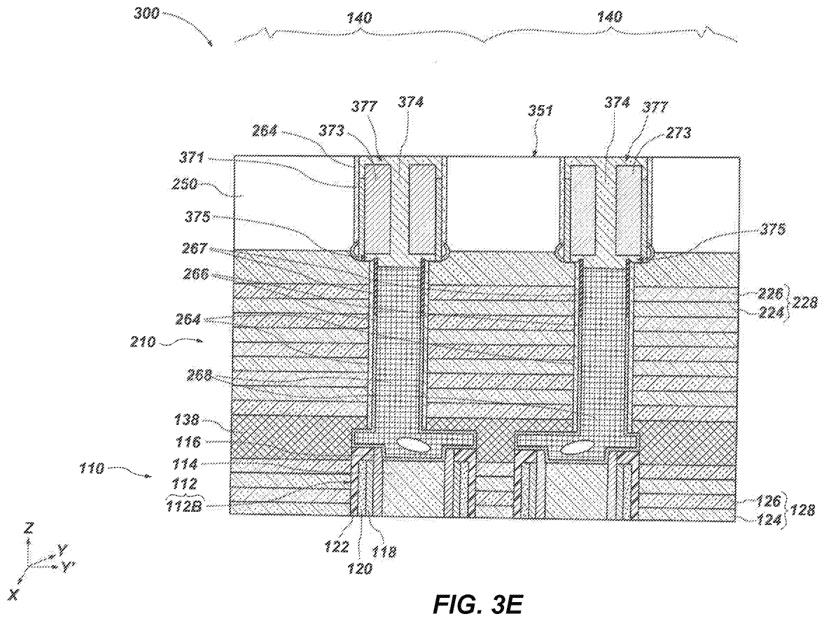

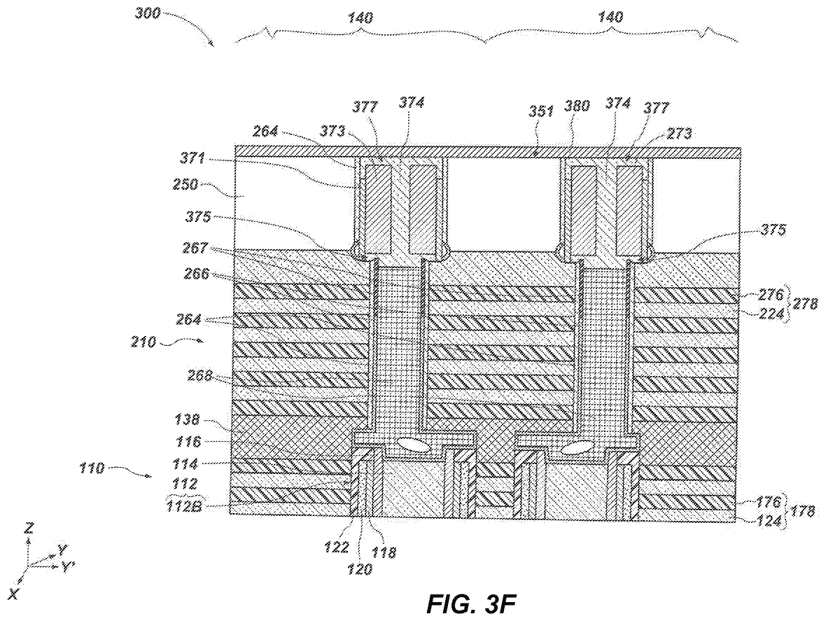

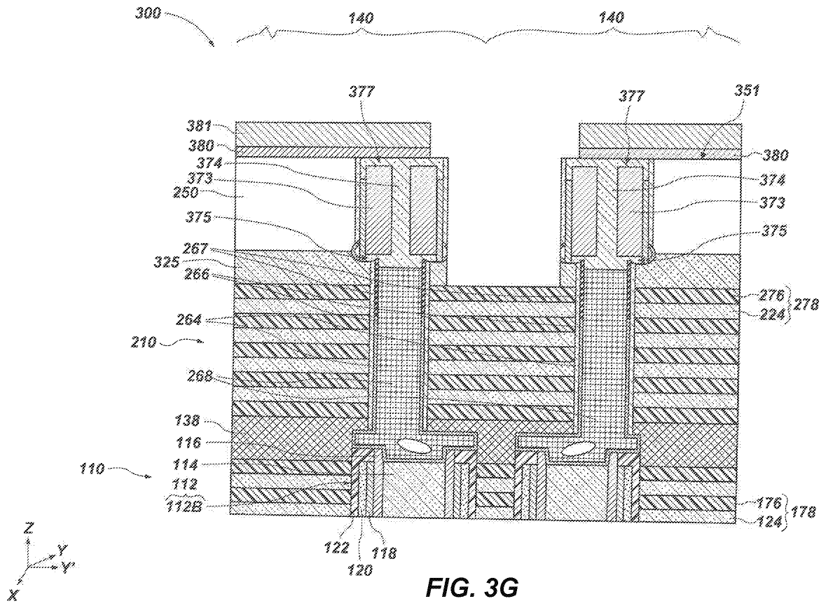

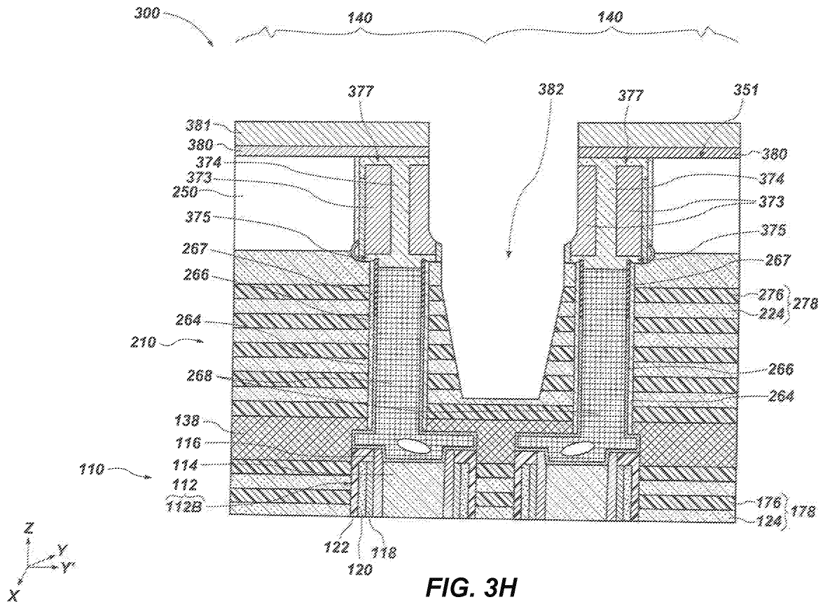

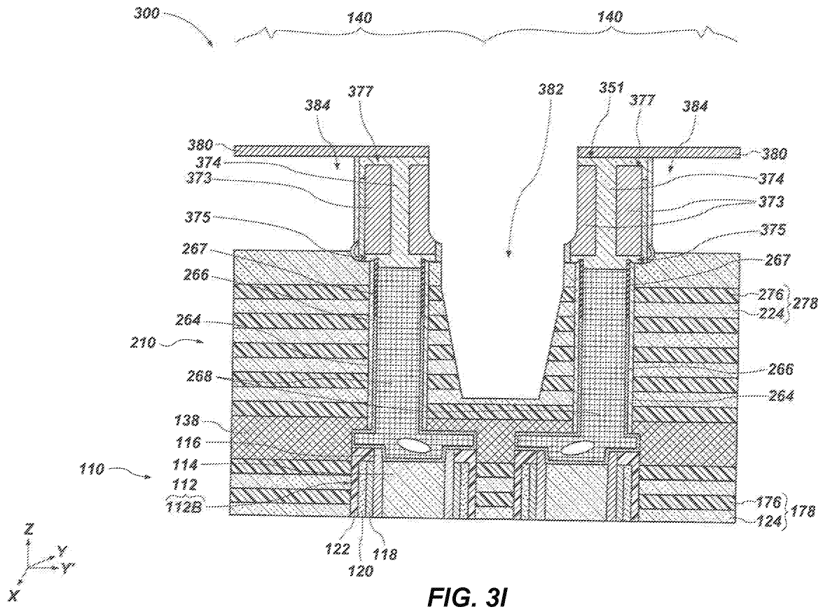

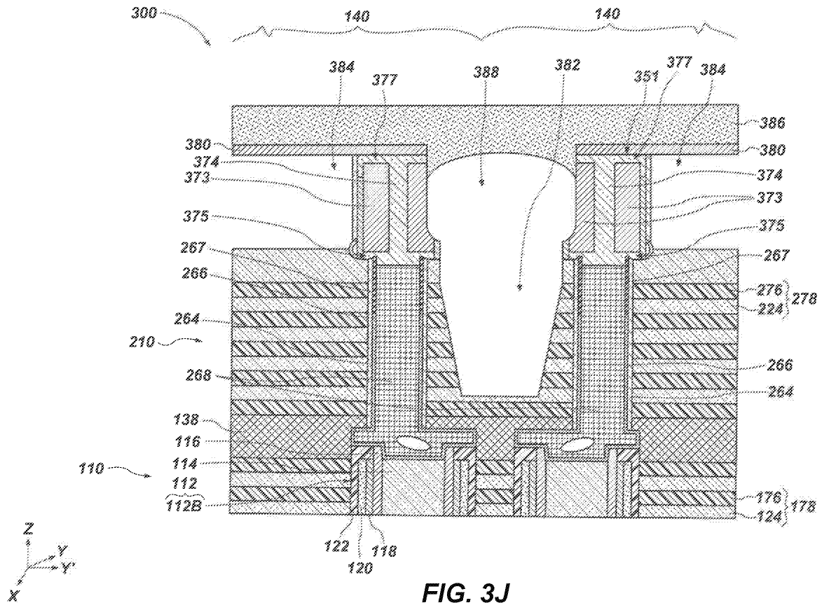

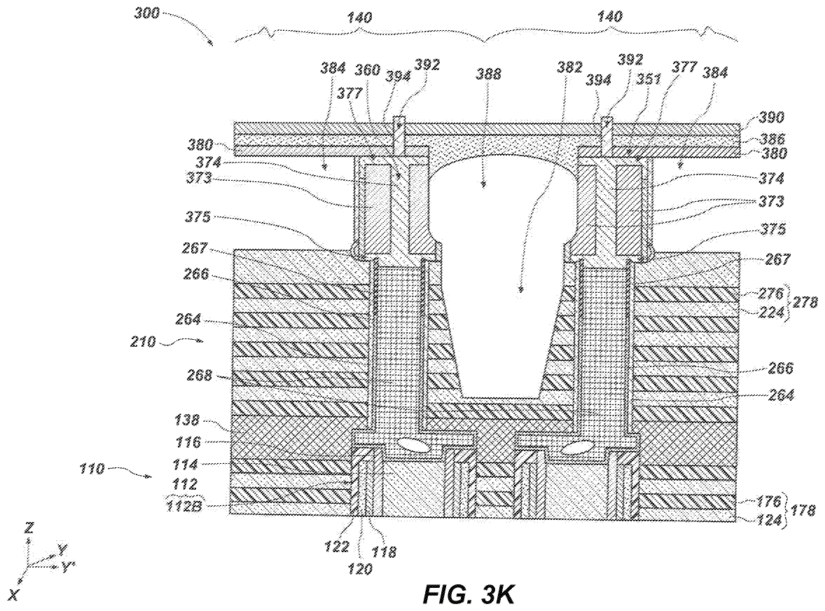

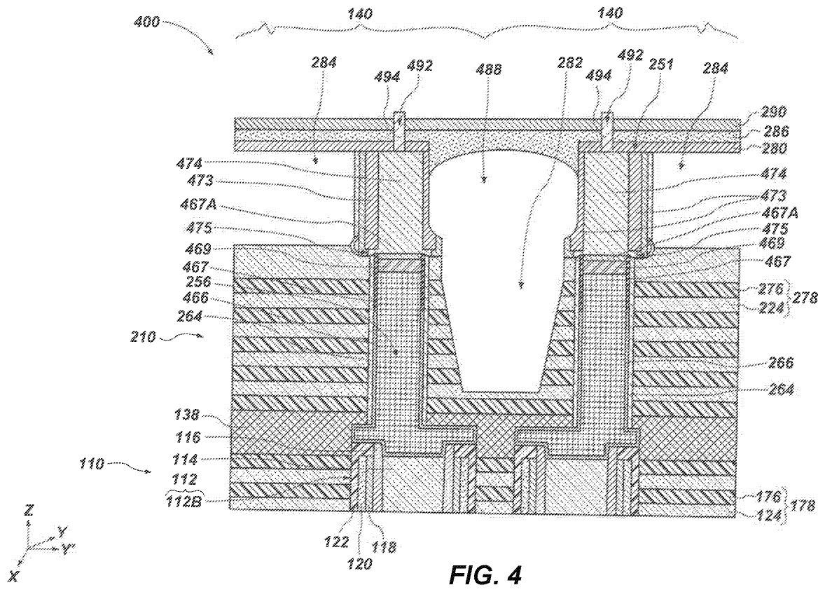

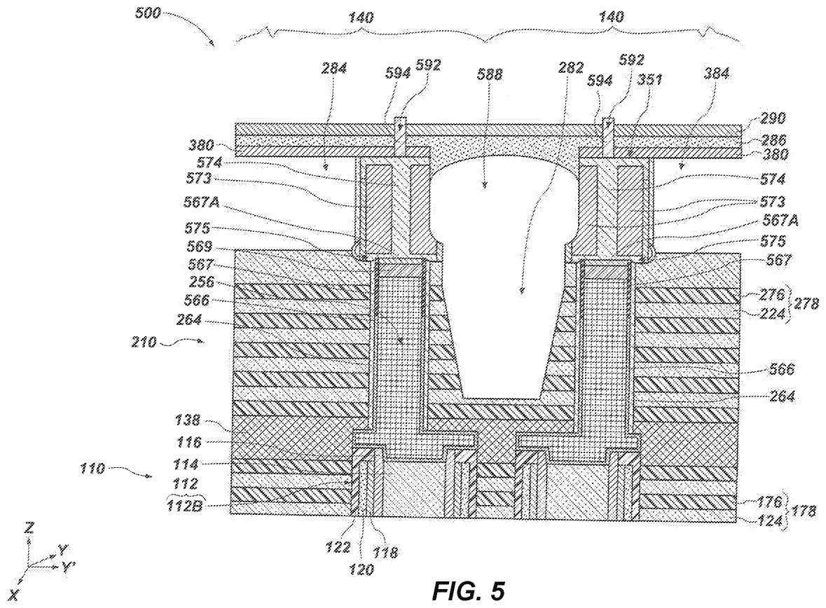

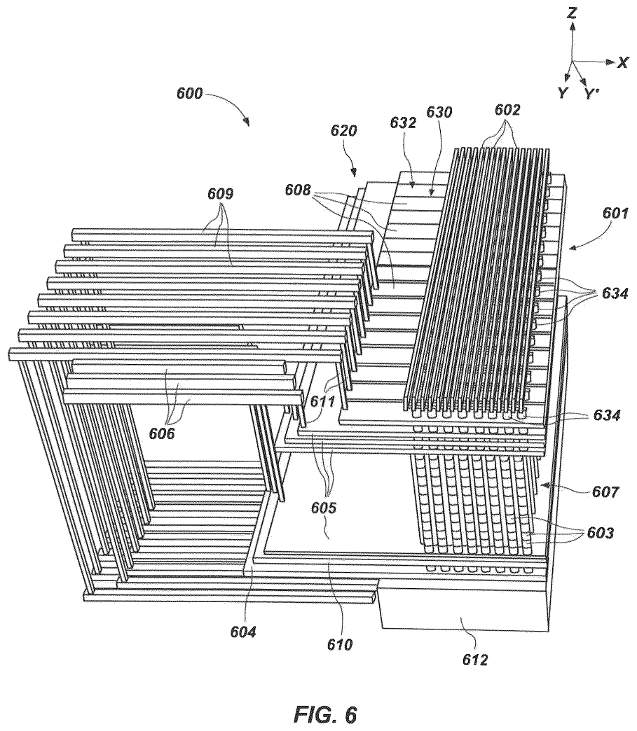

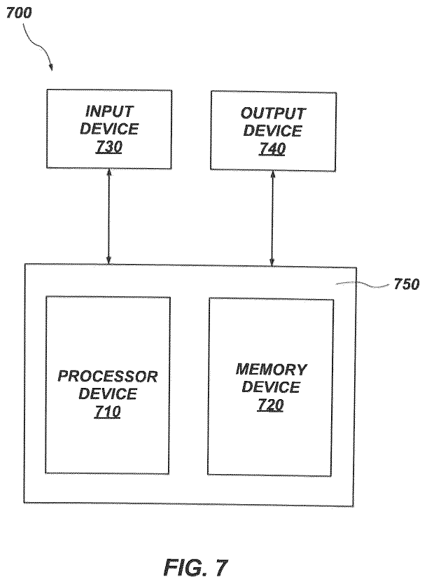

FIGS. 3Y through 3AD show simplified transverse cross section elevation views of the channel structures and conductive structures during further fabrication of isolation structures according to several embodiments.

FIG. 4AD and FIG. 5AD show simplified transverse cross section elevation views of alternative channel structures during further fabrication of isolation structures according to several embodiments.

FIG. 6 is a partial cutaway perspective view of an electronic device, in accordance with embodiments of the disclosure.

FIG. 7 is a block diagram of an electronic system, in accordance with embodiments of the disclosure.

### DETAILED DESCRIPTION

Microelectronic device structures (e.g., semiconductor device structures) that are assembled to make microelectronic devices, such as 3-dimensional not- and logic (3D NAND) memory devices, include strings of memory cells in a stack, where the strings of memory cells are coupled to source and drain select gate structures. The strings of memory cells individually comprise a channel material extending vertically through at least a portion of the stack. The microelectronic device comprises an additional stack (e.g., an upper stack structure, a select gate drain (SGD) stack structure) adjacent to (e.g., overlying) the stack, which comprises tiers of alternating additional conductive structures and additional insulative structures. Channel structures and pillar structures (also referred to as upper pillars) extend through the stack and additional stack. The microelectronic device also comprises conductive contacts above and adjacent to conductive structures that are positioned above the channel structures and pillar structures. Isolation structures that include, for example, air gaps or voids, laterally intervene between neighboring conductive structures. The isolation structures exhibit a weave pattern, and portions of the isolation structures are laterally adjacent to the conductive structures and portions of the channel structures. The isolation structures separate laterally adjacent conductive structures into sub-blocks.

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals may begin with the number of the drawing or a portion of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device structure or microelectronic device (e.g., a memory device, such as a 3D NAND Flash memory device) or a complete microelectronic device. The structures described below do not form a complete microelectronic device. Only those process acts, materials and structures necessary to understand the embodiments described herein are described in detail below. Additional acts to form a complete microelectronic device from the materials and structures may be performed by conventional techniques.

The materials described herein may be formed by conventional techniques including, but not limited to, spin coating, blanket coating, chemical vapor deposition (CVD), atomic layer deposition (ALD), plasma enhanced ALD (PEALD), physical vapor deposition (PVD), plasma enhanced chemical vapor deposition (PECVD), or low-pressure chemical vapor deposition (LPCVD). Alternatively, the materials may be grown in situ such as silicide structures and epitaxial structures. Depending on the specific material to be formed, the technique for depositing or growing the material may be selected by a person of ordinary skill in the art. The removal of materials may be accomplished by any suitable technique including, but not limited to, dry etching, wet (anisotropic) etching, abrasive planarization (e.g., chemical-mechanical planarization), or other known methods unless the context indicates otherwise.

As used herein, the term “air gap” means a volume extending into or through another region or material, or between regions or materials, leaving a void in that other region or material, or between regions or materials. The air gap may be unfilled (e.g., devoid) of a solid and/or liquid material. The air gap is not necessarily devoid of a material within its boundaries and may, for example, contain a gaseous material (e.g., air, oxygen, nitrogen, argon, helium, or a combination thereof) or a vacuum.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material, such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including a conductive material.

As used herein, “insulative material” means and includes electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including an insulative material.

As used herein, the term “integrated circuit” or “integrated-circuit device” may refer to a “microelectronic device” or a “nanoelectronic device,” each of which may be tied to a critical dimension exhibited by inspection. The term “integrated circuit” includes without limitation a memory device, as well as other devices (e.g., semiconductor devices) which may or may not incorporate memory. The term “integrated circuit” may include without limitation a logic device. The term “integrated circuit” may include without limitation a processor device such as a central-processing unit (CPU) or a graphics-processing unit (GPU). The term “integrated circuit” may include without limitation or a radiofrequency (RF) device. Further, an “integrated-circuit” device may incorporate memory in addition to other functions such as, for example, a so-called “system on a chip” (SoC) including a processor and memory, or an integrated-circuit device including logic and memory. Further, an “integrated-circuit” device may incorporate memory in addition to other functions such as, for example, a so-called “disaggregated-die device” where distinct integrated-circuit components are associated to produce the higher function such as that of an SoC, including a processor alone, a memory alone, a processor and a memory, or an integrated-circuit device including logic and memory. A disaggregated-die device may be a system-in-package (SiP) assembly that includes at least two of at least one logic processor, at least one graphics processor, at least one memory device such as a 3-dimensional NAND memory device, at least one radio-frequency device, at least one analog device such as a capacitor, an inductor, a resistor, a balun, and these several at least one SiP devices, among others, may be assembled and connected with at least one embedded, multi-die interconnect bridge (EMIB) device, and at least two of the devices may be coupled with through-silicon via (TSV) technologies.

As used herein, the term “selectively etchable” means and includes a material that exhibits a greater etch rate responsive to exposure to a given etch chemistry and/or process conditions relative to another material exposed to the same etch chemistry and/or process conditions. For example, the material may exhibit an etch rate that is at least about five times greater than the etch rate of another material, such as an etch rate of about ten times greater, about twenty times greater, or about forty times greater than the etch rate of the another material. Etch chemistries and etch conditions for selectively etching a desired material may be selected by a person of ordinary skill in the art. Where explicitly stated, etch selectivity may refer to a material that is selectively not etched by a given etch chemistry, compared to another given material.

According to embodiments described herein, a microelectronic device includes a first stack structure divided into block structures with vertically alternating sequences of first conductive structures and first insulative structures arranged in first tiers. Strings of memory cells vertically extend through the block structures of the first stack structure. A second stack structure vertically overlies the first stack structure and has a second vertical sequence of second conductive structures and second insulative structures arranged in second tiers. The second tiers may be configured as select gate drain (SGD) tiers that are part of a 3-dimensional, “not and” logic (3D NAND) memory device. Channel structures extend through the second stack structure and vertically overlie and are electrically coupled to the strings of memory cells. Each of the channel structures extend through conductive openings that have a first lateral dimension, and each of the channel structures surround insulative materials. The channel structures include enriched (e.g., doped) portions. Further, conductive structures vertically overlie the channel structures and metal silicide regions electrically contact the channel structures and the conductive structures. Each of the conductive structures extend through conductive structure openings that have a second lateral dimension that is larger than the first lateral dimension. The metal silicide regions contact each of the channel structures and the conductive structures.

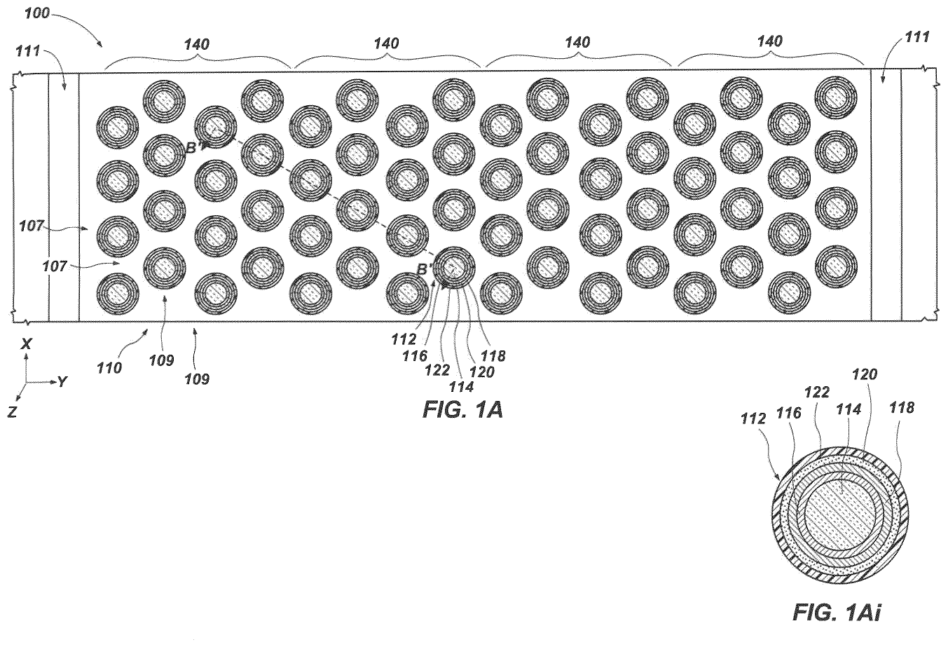

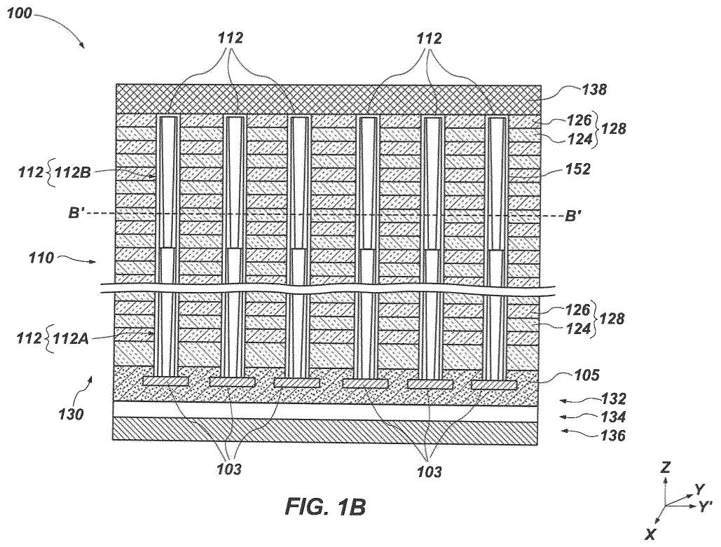

FIG. 1A is a simplified top plan view of a portion of a microelectronic device structure 100 that includes a first stack structure 110 that includes pillar structures 112 for precursor strings of memory cells. The pillar structures 112 (e.g., cell pillars) of materials may vertically extend (e.g., in the Z-direction) through the first stack structure 110. As will be described herein, the materials of the pillar structures 112 may form memory cells (e.g., strings of memory cells) during and after replacement-gate processing. The pillar structures 112 may each individually comprise an insulative material 114, a channel structure 116 horizontally neighboring the insulative material 114, a tunnel dielectric material (also referred to as a “tunneling dielectric material”) 118 horizontally neighboring the channel structure 116, a memory material 120 horizontally neighboring the tunnel dielectric material 118, and a dielectric blocking material (also referred to as a “charge blocking material”) 122 horizontally neighboring the memory material 120. The materials of the pillar structures 112 may be conformally formed so that thicknesses of the insulative material 114, the channel structure 116, the tunnel dielectric material 118 are substantially uniform.

Still referring again to FIG. 1A, the pillar structures 112 may be preliminarily identified in rows 107 (along a Y-direction) and columns 109 (along an X-direction), and the pillar structures 112 may be secondarily identified in pillar sectors 140 that will be demarcated within a second stack structure 210 (e.g., FIG. 2A). Further, the pillar structures 112 may be configured in a hexagonal arrangement, where an outer dimension may be seen to be hexagonal although seven pillar structures 112 are configured in a hexagonal close packed (HCP) arrangement. During further processing, a second stack structure 210 (FIG. 2A) is formed where the second stack structure 210 may also be referred to as a precursor of a select gate drain (SGD) structure.

FIG. 1Ai is an extract detail section of a top plan view of one of the pillar structures 112 according to some embodiments. Pillar structures 112 (e.g., cell pillars, memory pillars) of materials may vertically extend (e.g., in the Z-direction) through the first stack structure 110. The materials of the pillar structures 112 may form memory cells (e.g., strings of memory cells). The materials of the pillar structures 112 may be formed by conventional techniques. The insulative material 114 may be formed of and include an electrically insulative material such as, for example, phosphosilicate glass (PSG), borosilicate glass (BSG), fluorosilicate glass (FSG), borophosphosilicate glass (BPSG), silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide, a nitride material, (e.g., silicon nitride (Si₃N₄)), an oxynitride (e.g., silicon oxynitride), a dielectric carbon nitride material (e.g., silicon carbon nitride (SiCN)), a dielectric carboxynitride material (e.g., silicon carboxynitride (SiOCN)), or combinations thereof. In some embodiments, the insulative material 114 comprises silicon dioxide.

The material of the channel structure 116 may be formed of and include one or more of a semiconductor material (at least one elemental semiconductor material, such as polycrystalline silicon; at least one III-V compound semiconductor material, at least one II-VI compound semiconductor material, at least one organic semiconductor material, GaAs, InP, GaP, GaN, other semiconductor materials), and an oxide semiconductor material. In some embodiments, the channel structures 116 includes amorphous silicon or polysilicon. In some embodiments, the channel structure 116 comprises a doped semiconductor material.

The tunnel dielectric material 118 may be formed of and include a dielectric material through which charge tunneling can be performed under suitable electrical bias conditions, such as through hot-carrier injection or by Fowler-Nordheim tunneling induced charge transfer. By way of non-limiting example, the tunnel dielectric material 118 may be formed of and include one or more of silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In some embodiments, the tunnel dielectric material 118 comprises silicon dioxide. In other embodiments, the tunnel dielectric material 118 comprises silicon oxynitride.

The memory material 120 may comprise a charge trapping material or a conductive material. The memory material 120 may be formed of and include one or more of silicon nitride, silicon oxynitride, polysilicon (doped polysilicon), a conductive material (tungsten, molybdenum, tantalum, titanium, platinum, ruthenium, and alloys thereof, or a metal silicide such as tungsten silicide, molybdenum silicide, tantalum silicide, titanium silicide, nickel silicide, cobalt silicide, or a combination thereof), a semiconductive material polycrystalline or amorphous semiconductor material including at least one elemental semiconductor element or at least one compound semiconductor material, conductive nanoparticles (e.g., ruthenium nanoparticles), metal dots. In some embodiments, the memory material 120 comprises silicon nitride.

The dielectric blocking material 122 may be formed of and include a dielectric material such as, for example, one or more of an oxide (e.g., silicon dioxide), a nitride (silicon nitride), and an oxynitride (silicon oxynitride), or another material. In some embodiments, the dielectric blocking material 122 comprises silicon oxynitride.

In some embodiments, the tunnel dielectric material 118, the memory material 120, and the dielectric blocking material 122 together may comprise a structure configured to trap charge, such as, for example, an oxide-nitride-oxide (ONO) structure. In some such embodiments, the tunnel dielectric material 118 comprises silicon dioxide, the memory material 120 comprises silicon nitride, and the dielectric blocking material 122 comprises silicon dioxide.

FIG. 1B is a simplified transverse cross section elevational view of a portion of the first stack structure 110 of the microelectronic device structure 100 illustrated in FIG. 1A according to some embodiments. A section B′-B′ is taken along a diagonal of six pillar structures 112 in FIG. 1A. The pillar structures 112 may include first pillar structures 112A and second pillar structures 112B, where the second pillar structures 112B vertically overlie and are in electrical communication with the first pillar structures 112A. The pillar structures may also be referred to as lower pillar structures 112A and upper pillar structures 112B. The pillar structures 112 pass through vertically alternating sequences of first insulative structures 124 and second insulative structures 126 that are arranged in tiers 128. The first stack structure 110 also includes a source structure 130 of a source tier 132, an interconnect tier 134 and a routing tier 136.

The source tier 132 includes the discrete conductive structures 103 (e.g., discrete conductive island structures) horizontally separated (e.g., in the X-direction and in the Y-direction perpendicular to the X-direction) from one another. Dielectric material 105 may surround (e.g., horizontally surround, vertically surround) and be interposed between (e.g., in the X-direction and in the Y-direction) the discrete conductive structures 103. During processing and assembly, an interface dielectric structure 138 (e.g., an interdeck structure) is located above the tiers 128 and above and on the second pillar structures 112B.

Still referring to FIG. 1B, in some embodiments, a number (e.g., quantity) of tiers 128 of the first stack structure 110 may be within a range from 32 of the tiers 128 to 256 of the tiers 128. In some embodiments, the first stack structure 110 includes 128 of the tiers 128. However, the disclosure is not so limited, and the first stack structure 110 may include a different number of the tiers 128.

Still referring to FIG. 1B, the first insulative structures 124 may be formed of and include, for example, at least one dielectric material, such as one or more of an oxide material (e.g., silicon dioxide (SiO₂)), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), and aluminum oxide (Al₂O₃). In some embodiments, the first insulative structures 124 are formed of and include silicon dioxide. The second insulative structures 126 may be formed of and include an insulative material that is different than, and exhibits an etch selectivity with respect to, the first insulative structures 124. In some embodiments, the second insulative structures 126 are formed of and include a nitride material (e.g., silicon nitride (Si₃N₄)) or an oxynitride material (e.g., silicon oxynitride). In some embodiments, the second other insulative structures 126 comprise silicon nitride. During replacement gate processing, a wet etch chemistry is used that is selective to leaving the first insulative structures 124 and to removing (e.g., etching) the second insulative structures 126.

The source structure 130 may be formed of and include, for example, a semiconductor material doped with one or more n-type conductivity materials (e.g., polysilicon doped with at least one p-type dopant, such as one or more of boron, aluminum, and gallium) or one or more n-type conductivity materials (e.g., polysilicon doped with at least one n-type dopant, such as one or more of arsenic, phosphorous, antimony, and bismuth). The first stack structure 110 may be referred to herein as a deck structure or a first deck structure. Although FIG. 1B has been described and illustrated as including the first stack structure 110 directly over (e.g., on) the source structure 130, the disclosure is not so limited.

Still referring to FIG. 1B, the interface dielectric structure 138 may be located over an uppermost one of the tiers 128. The interface dielectric structure 138 may be formed of and include an electrically insulative material, such as, for example, one or more of phosphosilicate glass (PSG), borosilicate glass (BSG), fluorosilicate glass (FSG), borophosphosilicate glass (BPSG), and silicon dioxide. In some embodiments, the interface dielectric structure 138 comprises the same material composition as the first insulative structures 124. In some embodiments, the interface dielectric structure 138 comprises silicon dioxide.

FIG. 2A is a simplified transverse cross section elevational view of a microelectronic device structure 200 that is derived from and added to the microelectronic device structure 100 depicted in FIGS. 1A and 1B, where further processing has been accomplished according to some embodiments. Selected details of the pillar structures 112 (second pillar structures 112B) are set forth. For simplicity, only the second pillar structures 112B are shown in FIG. 2A, with the first pillar structures 112A (not shown) below the second pillar structures 112B. The second stack structure 210 may include alternating second stack first insulative materials 224 and second stack second insulative materials 226 that are arranged in second stack tiers 228. In some embodiments, five (5) repetitions of the second stack first insulative materials 224 and second stack second insulative materials 226 are assembled in second stack tiers 228 above the interface dielectric structure 138. A second insulative material 225 is formed over the second stack tiers 228 and a second stack upper material 250, such as a boron-doped polysilicon material, is formed over the second insulative material 225. The second pillar structures 112B include a sacrificial plug material 152, such as an undoped polysilicon plug, which is formed upon a sacrificial barrier material 154 such as a nitride barrier material. A thickness of the second stack upper material 250 may correspond to a desired thickness of a drain contact (see FIG. 2AD) electrically connected to the SGD structure. The thickness of the second stack upper material 250 may also correspond to a length of oxide spacer structures 273 (see FIGS. 2T-2V) used to align third conductive structures 274 and channel structures 266.

FIG. 2B is a cross section elevation view of the microelectronic device structure 200 depicted in FIG. 2A after a further processing act has been accomplished according to some embodiments. Second stack openings 255 are formed in the second stack structure 210 and the interface dielectric structure 138, to expose portions of the sacrificial plug material 152. Etch chemistries may be used that are selective to leave the sacrificial plug material 152, and to achieve material removal of exposed portions of the second stack upper material 250 and the second stack first insulative materials 224 and second stack second insulative materials 226. In example method embodiments, a masking material (not illustrated) is formed on the second stack upper material 250 and etching is done until the sacrificial plug material 152 is exposed, where the sacrificial plug material 152 functions as an etch stop to the selected etch chemistry. The several second stack openings 255 may be identified within the pillar sectors 140 by horizontal (Y′ direction) positions within the pillar sectors 140, including right second stack openings 255R, left second stack openings 255L, left-center second stack openings 255CL, and right-center second stack openings 255CR.

Still referring to FIG. 2B, further description of the second stack openings 255 is available by positional location of the second stack openings 255 above corresponding precursor strings of memory cells that arise from the pillar structures 112. For example, the right second stack openings 255R may have an offset geometry that may be horizontally offset from a symmetry line 211 (e.g., center line 211, radial symmetry line 211) of a corresponding precursor string of memory cells of the pillar structures 112, where the offset is quantified from the symmetry line 211, and the horizontal offset is partially quantified by lateral (Y′ direction) measurements from the symmetry line 211 by a first right offset distance 257R1, and a second right offset distance 257R2, where the two offset distances 257R1 and 257R2 substantially equal a symmetrical diameter distance of the second stack openings 255 (e.g., of the right second stack openings 255R). Similarly for example, the left second stack openings 255L may be horizontally offset from a center of a corresponding precursor string of memory cells of the pillar structures 112, where the offset is quantified from a symmetry line 211, and the horizontal offset is partially quantified by lateral (Y′ direction) measurements from the symmetry line 211 by a first left offset distance 257L1, and a second left offset distance 257L2, where the two offset distances 257L1 and 257L2 substantially equal a symmetrical diameter distance of the second stack openings 255. In some embodiments, the offset distances 257L1 and 257L2 are substantially the same within photolithographic variance for a given microelectronic device geometry. Similarly for right-center second stack openings 255CR, right-center second stack openings 255CR may be horizontally offset from a symmetry line 211 of a corresponding precursor string of memory cells of the pillar structures 112, where the offset is quantified from the symmetry line 211, and the horizontal offset is partially quantified by lateral (Y′ direction) measurements from the symmetry line 211 by a first right offset distance 257CR1, and a second right offset distance 257CR2, where the two offset distances 257CR1 and 257CR2 substantially equal a symmetrical diameter distance of the second stack openings 255. Further, and in comparison to relative offset distances for right second stack openings 255R and the right-center second stack openings 255CR, the right second stack openings 255R have a greater asymmetrical offset, quantified by the two offset distances 257R1 and 257R2, compared to the right-center second stack openings 255CR, where the two offset distances 257CR1 and 257CR2 may have a smaller difference in comparative lengths. In a non-limiting example embodiment, where the offset distances 257R1 and 257R2 equal unity, the offset distance 257R1 is in a range from about 0.2 of unity to about 0.35 of unity, and where the offset distances 257CR1 and 257CR2 equal unity, the offset distance 257CR1 is about 0.45 of unity to about 0.5 of unity. Further, and in comparison to relative offset distances for left second stack openings 255L and the left-center second stack openings 255CL, the left second stack openings 255L have a greater asymmetrical offset, quantified by the two offset distances 257L1 and 257L2, compared to the left-center second stack openings 255CL, where the two offset distances 257CL1 and 257CL2 may have a smaller difference in comparative lengths. In a non-limiting example embodiment, where the offset distances 257L1 and 257L2 equal unity, the offset distance 257L1 is in a range from about 0.2 of unity to about 0.35 of unity, and where the offset distances 257CL1 and 257CL2 equal unity, the offset distance 257CL1 is about 0.45 of unity to about 0.5 unity. In some embodiments, the offset distances may be such that the second stack openings 255 are substantially shifted such that the symmetry line 211 of the second pillar structures 112B does not pass through the center of the second stack openings 255.

Still referring to FIG. 2B, in some embodiments where e.g., the right second stack openings 255R have an offset geometry that may be horizontally offset from a symmetry line 211 (e.g., radial symmetry line 211) by about 20 nanometers (nm), the neighboring right-center second stack openings 255CR may only be shifted by about one half, e.g., about 10 nm. Relative offset amounts for second stack openings 255 may be selected to avoid undesirable issues with isolation structures 288 (see FIG. 2AC), while facilitating photolithographic processing usefulness for neighboring preliminary openings.

FIG. 2C is a cross section elevation view of the microelectronic device structure 200 depicted in FIG. 2B after further processing according to some embodiments. The second stack openings 255 are partially filled with a material, such as a carbon material 258, which may be formed by spinning on a dry carbon material precursor, followed by a dry stripping process that removes most of the carbon material precursor, except a portion of the carbon material precursor remains as the carbon material 258 within the second stack openings 255 above and on the sacrificial plug material 152.

FIG. 2D is a simplified transverse cross section elevation view of the microelectronic device structure 200 illustrated in FIG. 2C after further processing has been accomplished according to some embodiments. A material removal act has been accomplished to widen the second stack openings 255 in the second stack upper material 250 to form a conductive structure opening 260, which by completion of the conductive structure opening 260, further defines channel openings 256 below corresponding conductive structure openings 260. Removal of a portion of the second stack upper material 250 forms a step defined by sidewalls of the second stack upper material 250 and the second stack tiers 228 and a horizontal surface of the second insulative material 225. In other words, sidewalls of the conductive structure openings 260 and the channel openings 256 are not vertically aligned. Consequently, right conductive structure openings 260R have corresponding right channel openings 256R; left conductive structure openings 260L have corresponding left channel openings 256L; center-left conductive structure openings 260CL have corresponding center-left channel openings 256CL; and center-right conductive structure openings 260CR have corresponding center-right channel openings 256CR. The several offset distances illustrated in FIG. 2C, have been redefined due to etching of the second stack upper material 250, such that right conductive structure openings 260R may have respective first and second offset distances of 261R1 and 261R2, the left conductive structure openings 260L may have respective first and second offset distances of 261L1 and 261L2, the center-left conductive structure openings 260CL may have respective first and second offset distances of 261CL1 and 261CL2, and the center-right conductive structure openings 260CR may have respective first and second offset distances of 261CR1 and 261CR2 relative to the symmetry line 211. The offset distance proportions may be substantially preserved during removal of the second stack upper material 250 to form the conductive structure openings 260. In a non-limiting example embodiment, where the offset distances 261R1 and 261R2 equal unity, the offset distance 261R1 is in a range from about 0.2 of unity to about 0.35 of unity, and where the offset distances 261CR1 and 261CR2 equal unity, the offset distance 261CR1 is about 0.45 of unity to about 0.5 of unity. Further and in comparison to relative offset distances for left conductive structure openings 260L and the center-left conductive structure openings 260CL, the left conductive structure openings 260L have a greater asymmetrical offset, quantified by the two offset distances 261L1 and 261L2, compared to the center-left conductive structure openings 260CL, where the two offset distances 261CL1 and 261CL2 may have a smaller difference in comparative lengths. In a non-limiting example embodiment, where the offset distances 261L1 and 261L2 equal unity, the offset distance 261CL1 is in a range from about 0.2 of unity to about 0.35 of unity, and where the offset distances 261CL1 and 261CL2 equal unity, the offset distance 261CL1 is about 0.45 of unity to about 0.5 of unity. The offset distances may vary by pitch of the pillars, film thicknesses, and configurations of transistors and strings of memory cells in the microelectronic device structure 200.

FIG. 2E is a simplified transverse cross section elevation view of the microelectronic device structure 200 illustrated in FIG. 2D after further processing has been accomplished according to some embodiments. A material removal act has been accomplished to remove the carbon material 258. In some embodiments, a plug recess 262 may form in the sacrificial plug material 152, where the plug recess 262 may reflect the offset geometry of the channel openings 256. In some embodiments, the material removal act stops at the sacrificial plug material 152 such that no plug recess 262 forms.

FIG. 2F is a simplified transverse cross section elevation view of the microelectronic device structure 200 illustrated in FIG. 2E after further processing has been accomplished according to some embodiments. A gate oxide material 264 and, for example, a sacrificial polycrystalline silicon (“poly”) for channel structures 266, may each be conformally and continuously formed into the conductive structure openings 260 and the channel openings 256, and onto the sacrificial plug material 152. In some embodiments, the material removal act illustrated in FIG. 2E may stop at the sacrificial plug material 152, such that the gate oxide material 264 and sacrificial poly fills onto unetched upper surfaces of the sacrificial plug material 152.

FIG. 2G is a simplified transverse cross section elevation view of the microelectronic device structure 200 illustrated in FIG. 2F after further processing has been accomplished according to some embodiments. A spacer etch technique has removed horizontally oriented portions of the sacrificial poly above the plug recess 262 and also the spacer etch technique has removed the sacrificial poly above the second stack upper material 250. Consequently, the sacrificial poly is also removed at junctions between the conductive structure opening 260 and the channel opening 256.

Still referring to FIG. 2G and in some embodiments, the spacer etch technique includes first forming a protective material (not shown) at the top surfaces of the second stack upper material 250, and during the spacer etch, the spacer etch is done for a sufficient amount of time to also remove the gate oxide material 264 at the bottom of the channel openings 256 such that the sacrificial plug material 152 is exposed.

FIG. 2H is a simplified transverse cross section elevation view of the microelectronic device structure 200 illustrated in FIG. 2G after further processing of the microelectronic device structure 200 according to some embodiments. An etch process, such as an anisotropic wet etch, has been conducted to remove exposed portions of the gate oxide material 264 that was exposed in the spacer etch that was conducted in FIG. 2G. The etch process may also remove some of the interface dielectric structure 138, where the sacrificial poly remains, and where some of the gate oxide material 264 has also been removed to form a first undercut region 139 that is defined by surfaces of the second insulative material 225, the second stack upper material 250, the gate oxide material 264, and the sacrificial poly. Further, the plug recess 262, if present, is also exposed above the sacrificial plug material 152. Referring to the second stack upper material 250 and second stack structure 210 and second insulative material 225 that may be identical or similar to the second stack first insulative materials 224, the etch process may also accomplish material removal of some of each of the second stack upper material 250 and second stack, incidental second insulative materials 225 to form a second undercut region 249 that is defined by the second stack upper material 250 and second stack, and second insulative materials 225.

FIG. 2K is a simplified transverse cross section elevation view taken from a section 2K delineated in FIG. 2H by a dashed box, where a boundary between two adjacent pillar sectors 140 occurs, after further processing has been accomplished. The channel structure 266 (FIG. 2H) and the sacrificial plug material 152 have been removed by wet etching by use of an etch chemistry that is selective to leaving the remaining portions of the gate oxide material 264, as well as leaving the sacrificial barrier material 154. The removal process also leaves the second stack upper material 250, while effectively removing the sacrificial plug material 152.

FIG. 2M is a simplified transverse cross section elevation view taken from the microelectronic device structure 200 illustrated in FIG. 2K after a further processing act has been accomplished according to some embodiments. An etch process, such as a wet etch, has removed the sacrificial barrier material 154. In some embodiments, the sacrificial barrier material 154 is a nitride material, and the wet etch exposes the channel structures 116 in the second pillar structures 112B, in preparation for electrically connecting precursor strings of memory cells in the first stack structure 110 with electrically conductive structures in the second stack structure 210.

FIG. 2N is a simplified transverse cross section elevation view taken from the microelectronic device structure 200 illustrated in FIG. 2M after a further processing act has been accomplished according to some embodiments. Precursor channel material 265 is conformally formed within the channel openings 256 as well as within the conductive structure openings 260, where the precursor channel material 265 also contacts the channel structures 116 at upper portions of the first stack structure 110. The precursor channel material 265 may ultimately correspond to channel structure 266 (see FIG. 2R).

FIG. 2P is a simplified transverse cross section elevation view taken from the microelectronic device structure 200 illustrated in FIG. 2N after a further processing act has been accomplished according to some embodiments. An insulative material 268, such as an oxide material, is conformally formed to a thickness that substantially completely fills the channel openings 256, where drain select gate (SGD) transistors will be completed in the second stack structure 210. The formation of the insulative material 268 forms voids 271 in the conductive structure openings 260, laterally adjacent to the second stack upper material 250. A location and size of the voids 271 within the conductive structure openings 260 may be controlled by the process used to form the insulative material 268. The alignment tolerance between the pillar structures 112 and the channel structures 266 during the process of forming the microelectronic device structure 200 may be improved. The distance between the N+ doped drain and an uppermost wordline of the SGD transistor may be more tightly controlled, resulting in tighter gate induced drain leakage (GIDL) distributions and better device performance.

FIG. 2Q is a simplified transverse cross section elevation view taken from the microelectronic device structure 200 illustrated in FIG. 2P after a further processing act has been accomplished according to some embodiments. A wet chemistry oxide etch has removed a portion of the insulative material 268, particularly substantially completely from within the conductive structure openings 260. A portion of the insulative material 268, however, is not removed from within the channel openings 256, such that a neck region, near the second undercut region 249 that will form SGD structures, includes a remaining portion of the insulative material 268. Therefore, some residual insulative material 268 may remain within the second undercut region 249.

FIG. 2R is a simplified transverse cross section elevation view taken from the microelectronic device structure 200 illustrated in FIG. 2Q after a further processing act has been accomplished according to some embodiments. An etch process, such as a wet chemistry poly etch process, has removed a portion of the precursor channel material 265 that results in channel structures 266 remaining within the channel openings 256. The wet chemistry poly etch has removed the precursor channel material 265, particularly substantially completely from within the conductive structure openings 260. However, some of the insulative material 268 may remain within the channel openings 256, such that a neck region of the SGD structures includes a portion of the channel structures 266. Some residual precursor channel material 265 may remain within the second undercut region 249. The multi-directional etch processes described and illustrated in FIGS. 2Q and 2R enable the distance between the N⁺ doped drain and an uppermost wordline of the SGD transistor to be controlled.

FIG. 2S is a simplified transverse cross section elevation view taken from the microelectronic device structure 200 illustrated in FIG. 2R after a further processing act has been accomplished according to some embodiments. A doping process has been done, such as an N⁺ dopant implantation, a plasma-doped (PLAD) implantation, or a phosphorus-rich oxide implantation, such that doped (e.g., enriched) portions 267 of the channel structure 266 are formed, at least to a level of an uppermost second stack tier 228 of second stack second insulative materials 226 within the second stack structure 210. In future processing acts, replacement-gate techniques remove and replace the second insulative structures 126 in the first stack structure 110 and the second stack second insulative materials 226 in the second stack structure 210 with a conductive material, and electrical conductivity may be achieved at least between the doped portions 267 of the channel structures 266, with second conductive structures 276 (see e.g., FIG. 2Y and FIG. 3Y) within the second stack structure 210.

Still referring to FIG. 2S, by formation of the widened conductive structure openings 260, the doping process to form the doped portions 267 of the channel structures 266 may be more controllable to achieve doping depths that may stop at or below the level of the uppermost second stack second insulative material 226, where after replacement-gate processing, the doped portions 267 of the channel structure 266 contact only the uppermost second conductive structure 276 (see, e.g., FIG. 2Y) within the second stack structure 210 that has replaced the uppermost second stack second insulative material 226 (see, e.g., FIG. 2X) within the second stack structure 210. Consequently, as an SGD structure that is formed and that will be contained within the second stack structure 210, distribution depth and concentrations of the distribution depths of the doped portions 267 are more controllably formed. The increased dopant control may reduce variation in GIDL of the microelectronic device structure 200.

FIG. 2T is a simplified transverse cross section elevation view taken from the microelectronic device structure 200 illustrated in FIG. 2S after a further processing act has been accomplished according to some embodiments. A nitride material 270 may be conformally formed into the conductive structure openings 260, followed by an oxide material 272, where the oxide material 272 has a thickness that partially fills the conductive structure openings 260. However, a portion of the conductive structure openings 260 remains open, with the remaining volume of the openings being instrumental in defining the thickness (X-Y dimensions) of the third conductive structures 274 (see FIG. 2Y) that will be located in the conductive structure openings 260. A diameter of the third conductive structures 274 may be substantially equal to the diameter of the openings remaining unfilled in FIG. 2T.

FIG. 2U is a simplified transverse cross section elevation view of the microelectronic device structure 200 illustrated in FIG. 2T after a further processing act has been accomplished according to some embodiments. A etch process may be conducted using an etch chemistry formulated to remove substantially horizontal portions of the oxide material 272, leaving oxide spacer structures 273 formed from the substantially vertical portions of the oxide material 272. The oxide spacer structures 273 fill a portion of the conductive structure openings 260, and the etch process exposes the nitride material 270 at the bottom of the conductive structure openings 260.

FIG. 2V is a simplified transverse cross section elevation view of the microelectronic device structure 200 illustrated in FIG. 2U after a further processing act has been accomplished according to some embodiments. A wet nitride etch process may be conducted using an etch chemistry formulated to remove substantially horizontal portions of the nitride material 270 over the second stack upper material 250 and within the conductive structure openings 260, to expose upper surfaces of the second stack upper material 250 and the doped portions 267 of the channel structures 266, such that a portion of the conductive structure openings 260 proximal to the channel structures 266 has a greater width than a portion of the conductive structure openings 260 distal to the channel structures 266. The nitride material 270 (e.g., FIG. 2U) may be changed in one or more dimension to be a nitride material 270.

FIG. 2W is a simplified transverse cross section elevation view of the microelectronic device structure 200 illustrated in FIG. 2V after a further processing act has been accomplished according to some embodiments. A directional etch is done using an etch chemistry formulated to remove portions of the insulative material 268 such that upper surfaces 269L and 269R of the insulative material 268 are recessed, exposing top surfaces 267T and side (lateral) surfaces 267S, such that the doped portions 267 of the channel structures 266 have increased exposed surface area. The increased surface area is sufficient to provide electrical contact between poly material within the channel openings 256 and conductive material of third conductive structures 274 (FIG. 2X) that may be formed in the conductive structure openings 260. The upper surfaces 269L and 269R of the insulative material 268 are recessed below an upper surface of the doped portions 267 of the channel structures 266.

Still referring to FIG. 2W, the etch chemistries for the directional etch process may also remove residual native oxides (not shown) on exposed portions of the top surfaces 267T and side (lateral) surfaces 267S of the doped portions 267 of the channel structures 266. Consequently, when e.g., the third conductive structures 274 (FIG. 2X) are formed, electrical interconnection between the channel structures 266 and the third conductive structures 274 (FIG. 2X) may be improved.

FIG. 2X is a simplified transverse cross section elevation view of the microelectronic device structure 200 illustrated in FIG. 2W after a further processing act has been accomplished according to some embodiments. Third conductive structures 274 have been formed in the conductive structure openings 260, substantially filling the conductive structure openings 260, including in the second undercut region 249. A portion of the third conductive structures 274 may, therefore, intervene between the oxide spacer structures 273 and the doped portions 267 of the channel structure 266. The process may include first forming a seed liner material (e.g., titanium), followed by forming a barrier material (e.g., titanium nitride) on the seed liner material, followed by forming a conductive material (e.g., tungsten) in the conductive structure opening 260. While the third conductive structures 274 may include multiple materials, FIG. 2X shows the third conductive structures 274 as a single material for simplicity. A width (e.g., diameter) of the third conductive structures 274 proximal to the second undercut region 249 is greater than a width (e.g., diameter) of the third conductive structures 274 laterally adjacent to the second stack upper material 250. The third conductive structures 274 include a widened portion 275 exhibiting the increased width, while the width of the third conductive structures 274 laterally adjacent to the second stack upper material 250 is reduced in comparison. After formation of the third conductive structures 274, a planarizing act may be conducted, such as chemical mechanical polishing (CMP), to achieve a substantially planar upper surface 251 that includes the second stack upper material 250 and the third conductive structures 274, among other exposed structures. Incidental to formation of the third conductive structures 274 and in other regions of the microelectronic device structure 200, contacts may be formed at or near the processing act(s) illustrated, such as in staircase regions (see e.g., staircase structures 620, FIG. 6) of the microelectronic device structure 200.

Still referring to FIG. 2X, the channel structures 266, including the doped portions 267 of the channel structures 266, extend vertically along the second stack second insulative material 226 of the second stack tiers 228. The channel structures 266 have a substantially uniform width when seen in cross section. In three dimensional views, the channel structures 266, including the doped portions 267, have an elongate right cylinder shape. In the cross section of FIG. 2X, the channel structures 266, including the doped portions 267, have an elongate rectangular shape.

FIG. 2XT is a simplified top plan and partial cut-away view of the microelectronic device structure 200 illustrated in FIG. 2X, with additional structure similar to the view illustrated in FIG. 1A according to some embodiments. The third conductive structures 274 are positioned above the pillar structures 112, with the third conductive structures 274 horizontally offset from a center of the pillar structures 112. In other words, the third conductive structures 274 are aligned with the insulative material 268 but are not aligned with (e.g., are offset from) the symmetry lines 211 of the pillar structures 112.

Still referring to FIG. 2XT, precursor slot structures 111 may be formed through each of the first stack structure 110 and the second stack structure 210 for use during further processing. The slot structures 111 may be referred to herein as so-called “replacement gate” slot structures. The slot structures 111 may be formed by removing portions of the materials of the second stack structure 210, the interface dielectric structure 138, and the first stack structure 110. The materials of the second stack structure 210, the interface dielectric structure 138, and the first stack structure 110 may, for example, be removed by one or more etch processes. The slot structures 111 may be formed within a staircase region of the microelectronic device structure 200.

FIG. 2Xi is an enlarged view of a detail section 2Xi, of the microelectronic device structure 200 illustrated in FIG. 2X, according to some embodiments. After formation of the third conductive structures 274 against both the top surfaces 267T and side (lateral) surfaces 267S, a siliciding process may be conducted by applying thermal energy. The top surfaces 267T and the side lateral surfaces 267S of the third conductive structures 274 are converted to a metal silicide region 267A. The metal silicide region 267A forms continuous electrically conductive interfaces between the doped portions 267 of the channel structures 266 and the third conductive structures 274. The metal silicide region 267A separates the gate oxide material 264 and the third conductive structures 274, and the portion of the third conductive structures 274 in the second undercut region separates the oxide spacer structures 273 from the doped portions 267 of the channel structures 266.

FIG. 2Y is a simplified transverse cross section elevation view of the microelectronic device structure 200 illustrated in FIG. 2X after a further processing act has been accomplished according to some embodiments. Replacement-gate processing is accomplished by forming an oxide material 280 on the upper surface 251, patterning the oxide material 280 to form slits (not illustrated) within different regions (not illustrated) of the microelectronic device structure 200, and oxidizing exposed portions of the second stack upper material 250. Thereafter, replacement-gate processing includes removing the nitride materials of the second insulative structures 126 in the first stack structure 110 and of the second stack second insulative materials 226 in the second stack structure 210. Further, first conductive structures 176 are formed within the first stack structure 110 between vertically adjacent first insulative structures 124, as well as second conductive structures 276 are formed within the second stack structure 210 between vertically adjacent second stack first insulative materials 224. Consequently, tiers 178 are formed within the first stack structure 110 and tiers 278 within the second stack structure 210 that each have first conductive structures 176 and second conductive structures 276, respectively.

Still referring to FIG. 2Y, after removal of the second insulative structures 126, the first conductive structures 176 and the second conductive structures 276 may be formed between the respective neighboring first insulative structures 124 of the first stack structure 110, and the second stack first insulative materials 224 of the second stack structure, such that the first tiers 178 and second tiers 278 are formed. The second conductive structures 276 may comprise the same material composition as the first conductive structures 176. The second conductive structures 276 of the first stack structure 110 may function as local word line structures (e.g., local or word line plates). Lower portions of the channel structures 266 may be laterally adjacent to lower portions of the second conductive structures 276, and upper portions of the channel structures 266 may be laterally adjacent to upper portions of the second conductive structures 276. The doped portions 267 of the channel structures 266 may be located above uppermost second conductive structures 276. The second conductive structures 276 of the second stack structure 210 may function as select gate structures, such as select gate drain (SGD) structures. Accordingly, the second conductive structures 276 within the upper portions of the second tiers 278 may function as so-called “de-integrated SGDs.”

The first conductive structures 176 and the second conductive structures 276 may each individually be formed of and include a conductive material. In some embodiments, the first conductive structures 176 and the second conductive structures 276 comprise tungsten. In other embodiments, the first conductive structures 176 and the second conductive structures 276 comprise conductively doped polysilicon.

In some embodiments, the first conductive structures 176 may include a conductive liner material (not shown) around the first conductive structures 176, such as between the first conductive structures 176 and the first insulative structures 124. In addition, the second conductive structures 276 may include a conductive liner material (not shown) around the second conductive structures 276, such as between the second tier second conductive structures 276 and the second stack first insulative materials 224. The conductive liner material may comprise, for example, a seed material from which the first conductive structures 176 and second conductive structures 276 may be formed. The conductive liner material may be formed of and include, for example, a metal (e.g., titanium, tantalum), a metal nitride (e.g., tungsten nitride, titanium nitride, tantalum nitride), or another material. In some embodiments, the conductive liner material comprises titanium nitride.

The first conductive structures 176 may function as electrical communication to vertical strings 607 of memory cells 603 (FIG. 6). The memory cells 603 of the vertical strings 607 (FIG. 6) may be located at intersections of the pillar structures 112 and the first conductive structures 176 and may individually include a portion of one of the pillar structures 112 and a portion of one of the first conductive structures 176. Vertically neighboring memory cells 603 of the vertical strings 607 (FIG. 6) may be separated from each other by one of the first insulative structures 124.

FIG. 2Z is a simplified transverse cross section elevation view of the microelectronic device structure 200 illustrated in FIG. 2Y after further processing acts have been accomplished according to some embodiments. A masking material 281 has been formed and patterned above the upper surface 251, and at an intersection between two pillar sectors 140, followed by an oxide etch process to remove the oxide material 280 on the upper surface 251. Thereafter, an etch process may be conducted to remove the second stack upper material 250 exposed between the patterned masking material 281, where the etch process is stopped by the second insulative material 225 that is below the second stack upper material 250 and that is above the upper occurrence of the conductive material within the tiers 278. An oxide etch process may subsequently be conducted that further removes materials until exposing an uppermost one of the second conductive structures 276. The second conductive structures 276 may function as word lines after further processing.

FIG. 2AA is a simplified transverse cross section elevation view of the microelectronic device structure 200 illustrated in FIG. 2Z after a further processing act has been conducted according to some embodiments. Sub-block segmentation has been accomplished at the level of the second stack structure 210 by removing (e.g., etching) materials at the intersection between two pillar sectors 140, forming a sub-block recess 282. The sub-block recess 282 is formed through most of the second tiers 278. The removal of the materials of the second tiers 278 to form the sub-block recess 282 is a self-aligned process where the oxide spacer structures 273 are substantially resistant to the etch chemistries used to achieve directional etching of the second stack first insulative materials 224 and of the second conductive structures 276. The self-aligned directional etching leaves the sub-block recess 282 at the boundaries between two pillar sectors 140. The sub-block recess 282 has different widths along different portions of its length. For instance, portions of the sub-block recess 282 proximal to the interface dielectric structure 138 are narrower than portions of the sub-block recess 282 distal to the interface dielectric structure 138. In other words, the portions of the sub-block recess 282 laterally adjacent to the third conductive structures 274 are wider than the portions of the sub-block recess 282 laterally adjacent to the tiers 278 and insulative material 268 of the second stack structure 210.

Still referring to FIG. 2AA, after the self-aligned etch is conducted, new dimensions may exist, e.g., for the right conductive structure openings 260RA may have respective first and second offset distances of 261R1A and 261R2, where the first offset distance 261R1A is less than the previous first offset distance 261R1 (e.g., FIG. 2S). The first offset distance 261R1A is shorter by virtue of the spacer etch process. In some embodiments, where spacer etching is conducted for a sufficient amount of time, the sum of the first and second offset distances 261R1A and 261R2 may approach or be approximately equal to the sum of the first and second offset distances 257R1 and 257R2. In any event, for right and left conductive structure openings 260RA and 260LA the conductive structure openings 260 are wider than the channel openings 256 (e.g., FIG. 2W).

FIG. 2AB is a simplified transverse cross section elevation view of the microelectronic device structure 200 illustrated in FIG. 2AA after a further processing act has been accomplished according to some embodiments. The masking material 281 (FIG. 2AA) may be removed and a wet etch process conducted that selectively removes the second stack upper material 250, while the second conductive structures 276 and the second stack first insulative material 224 of the second tiers 278, and the oxide material 280 remain. Consequently, second stack chambers 284 are formed at an elevation laterally adjacent to an upper portion of the sub-block recess 282 that is self-aligned between third conductive structures 274.

FIG. 2AC is a simplified transverse cross section elevation view of the microelectronic device structure 200 illustrated in FIG. 2AB after a further processing act has been conducted according to some embodiments. A non-conformal oxide material 286 may be non-conformally formed over the oxide material 280. The non-conformal oxide material 286 may also be formed on sidewalls of the oxide spacer structures 273. Therefore, the non-conformal oxide material 286 is formed partially into the area of the sub-block recess 282 and also bridges over the sub-block recess 282, such that an isolation structure 288 (e.g., air gap 288) is formed. The isolation structure 288 may be a closed cell that contains a gas or vacuum that is present during the non-conformal deposition process. Put another way, the non-conformal oxide material 286 defines an upper surface of the isolation structure 288, and materials of the tiers 278 define sidewalls and a lower surface of the isolation structure 288 between the selected third conductive structures 274. Since the sub-block recess 282 has different widths along different portions of its length, portions of the isolation structure 288 proximal to the interface dielectric structure 138 are narrower than portions of the isolation structure 288 distal to the interface dielectric structure 138. In other words, the portions of the isolation structure 288 laterally adjacent to the third conductive structures 274 are wider than the portions of the isolation structure 288 laterally adjacent to the tiers 278 of the second stack structure 210. By forming the isolation structure 288 between the neighboring third conductive structures 274, alignment tolerance during the process of forming the microelectronic device structure 200 may be improved.

FIG. 2AD is a simplified transverse cross section elevation view of the microelectronic device structure 200 illustrated in FIG. 2AC after a further processing act has been conducted according to some embodiments. The non-conformal oxide material 286 may be planarized and its height reduced, and a nitride material 290 may be formed over the non-conformal oxide material 286. Thereafter, a masking material (not shown) is patterned, bit line contact openings 292 are formed, and bit line contacts 294 are formed in the bit line contact openings 292, followed by removing the masking material. The bit line contacts 294 may, for example, be tungsten bit line contacts. The bit line contacts 294 provide electrical communication from the channel structures 266 and the third conductive structures 274 to other conductive structures of the microelectronic device structure 200. The bit line contacts 294 in the bit line contact openings 292 provide the electrical communication to the pillar structures 112 to comprise strings of memory cells within the first stack structure 110.

Still referring to FIG. 2AD, formation of the third conductive structures 274 within the conductive structure openings 260, where the conductive structure openings 260 (FIGS. 2D and 2E) are wider than the channel openings 256 (FIGS. 2D and 2E), allows for increased dopant amounts to form the doped portions 267 of the channel structures 266, which may result in lower capacitance within the third conductive structures 274, which is useful for signal conveyance between the vertical strings 607 (FIG. 6) of memory cells 603 (FIG. 6) and other structures within a microelectronic device such as a 3D NAND memory device (see FIG. 6). However, electronic device configurations other than a 3D NAND memory device may include the third conductive structures 274.

Referring again to FIG. 2AD, formation of the third conductive structures 274 within the conductive structure openings 360, where the conductive structure openings 360 are wider than the channel openings 256, allows for improved doping to form the doped portions 267 of the channel structures 266, which allows for improved lower capacitance issues within the third conductive structures 274, which is useful for signal conveyance between the vertical strings 607 (FIG. 6) of memory cells 603 (FIG. 6) and other structures within a microelectronic device such as a 3D NAND memory device (see FIG. 6).

FIG. 2ADT is a simplified top view of the microelectronic device structure 200 illustrated in FIG. 2AD according to several embodiments. The isolation structures 288 (also referred to as air gaps 288) are configured as a weave pattern among selections of two adjacent columns 109 at boundaries between two pillar sectors 140. The isolation structures 288 have a closed cell configuration that contains the ambient gas (e.g., air, vacuum) that is enclosed during the non-conformal deposition process. The isolation structures 288 demarcate pillar sectors 140 within an array region of a 3D NAND microelectronic device 600 (FIG. 6).

FIGS. 1A-2AD and the accompanying description describe and illustrate the formation of the third conductive structures 274 laterally adjacent to the isolation structures 288, with the width of the third conductive structures 274 being substantially uniform along a length thereof. A portion of the third conductive structures 274 may exhibit the widened portion 275 proximal to the channel structures 266. However, different configurations of the third conductive structures 274 may be achieved, as described below and illustrated in FIGS. 3T-3AD, where a relatively greater proportion of the third conductive structures 374 do not exhibit a substantially uniform width along a length thereof. A microelectronic device structure 300 as shown in FIG. 3T may be formed as previously described with respect to FIGS. 2A-2S.

FIG. 3T is a simplified transverse cross section elevation view of the microelectronic device structure 300, at a similar stage of process as the microelectronic device structure 200 illustrated in FIG. 2S after a further processing act has been accomplished according to some embodiments. FIG. 3T illustrates embodiments that may stem from previously presented processing up to and including processing of the microelectronic device structures 200 represented in FIG. 2S. A nitride material 370 is conformally formed into conductive structure openings 360, followed by an oxide material 372, where the oxide material 372 has a thickness that partially fills the conductive structure openings 360. A portion of the conductive structure openings 360 remains open, with the remaining volume of the openings being instrumental in defining the thickness (X-Y dimensions) of third conductive structures 374 (see FIG. 3X) that may ultimately be formed in the conductive structure openings 360. By comparison to the conductive structure openings 260 illustrated in FIG. 2T, the remaining volume of the conductive structure openings 360 is smaller, which will result in thinner third conductive structures 374 (see FIG. 3X) compared to the third conductive structures 274 (FIG. 2X). In other words, the oxide material 372 is formed in the conductive structure openings 360 at a greater thickness than the oxide material 272 is formed in the conductive structure openings 260. A diameter of a portion of the third conductive structures 374 may be substantially equal to the diameter of the openings remaining unfilled in FIG. 3T. Other features of the microelectronic device structure 300 shown in FIG. 3T may be formed as previously described with respect to FIG. 2T.

FIG. 3U is a simplified transverse cross section elevation view of the microelectronic device structure 300 illustrated in FIG. 3T after a further processing act has been accomplished according to some embodiments. A spacer etch process is conducted using an etch chemistry that is formulated to remove substantially horizontally oriented portions of the oxide material 372, leaving oxide spacer structures 373 formed from the substantially vertical portions of the oxide material 372. The oxide spacer structures 373 fill a portion of the conductive structure openings 360, and the etch process exposes the nitride material 370 at the bottom of the conductive structure openings 360. The spacer etch process also removes a portion of the oxide material 372 within the conductive structure openings 360 such that so-called “T-shaped” conductive structure openings 360R are formed. The T-shaped opening results in the formation of the third conductive structures 374 having relatively wider and relatively narrower portions. Other features of the microelectronic device structure 300 shown in FIG. 3U may be formed as previously described with respect to FIG. 2U.

FIG. 3V is a simplified transverse cross section elevation view of the microelectronic device structure 300 illustrated in FIG. 3U after a further processing act has been accomplished according to some embodiments. A wet nitride etch process may be conducted using an etch chemistry formulated to remove substantially horizontal portions of the nitride material 370 over the second stack upper material 250 and within the conductive structure openings 360, to expose upper portions of the doped portions 267 of the channel structures 266, such that portions 361L and 361R of the conductive structure openings 360 are wider than portions of the conductive structure openings 360 between the oxide spacer structures 373. The portions 361L and 361R have a greater lateral (X-Y) dimension than that of conductive structure openings 360. Because of the recessed oxide spacer structures 373, the nitride etch process also removes upper portions of the nitride material 370 such that the conductive structure openings 360 includes widened portions 361L, 361R that extend between the recessed oxide spacer structure 373 and residual portions of the gate oxide material 264 that remains adjacent the second stack upper material 250. After forming the third conductive structures 374 in the openings, the third conductive structures 374 include first elongate portions 374A, first widened portions 375, and second widened portions 377 (see, e.g., FIG. 3X). The nitride material 370 (e.g., FIG. 3U) is altered in structure to be a nitride material 371. Other features of the microelectronic device structure 300 shown in FIG. 3V may be formed as previously described with respect to FIG. 2V.

FIG. 3W is a simplified transverse cross section elevation view of the microelectronic device structure 300 illustrated in FIG. 3V after a further processing act has been accomplished according to some embodiments. A directional oxide etch is conducted using an etch chemistry formulated to remove portions of the oxide fill material 268 that remains in the channel openings 256, such that recessed upper surfaces 369R of the oxide fill material 268 expose both top surfaces 367T and side (lateral) surface 367S. Therefore, the doped portions 267 of the channel structures 266 have increased exposed surface area, sufficient to provide increased contact between the material of the third conductive structures 374 in the channel openings 256 and the doped portions 267. Other features of the microelectronic device structure 300 shown in FIG. 3W may be formed as previously described with respect to FIG. 2W.

Still referring to FIG. 3W, the etch chemistries for the directional etch process may also remove residual native oxides (not shown) on exposed portions of the top surfaces 267T and side (lateral) surfaces 267S of the doped portions 267 of the channel structures 266. Consequently when e.g., the third conductive structures 374 are formed, electrical interconnection between the channel structures 266 and the third conductive structures 374 may be improved.

FIG. 3X is a simplified transverse cross section elevation view of the microelectronic device structure 300 illustrated in FIG. 3W after a further processing act has been accomplished according to some embodiments. A conductive material may be formed in the conductive structure openings 360 to form the third conductive structures 374. For example, a seed liner material (e.g., titanium) may be formed, followed by forming a titanium nitride material on the seed liner material, followed by a metal (e.g., tungsten) deposition into the conductive structure opening 360. The third conductive structures 374 include first elongate portions 374A, first widened portions 375, and second widened portions 377. The first widened portions 375 are in the portions 361L and 361R of the conductive structure openings 360 and have a greater lateral (X-Y) dimension than that of the first elongate portions 374A. The second widened portions 377 are in the second widened portions 363R and 363L above the recessed oxide spacer structures 373. The first widened portions 375 contact the insulative material 268, the doped portions 267, the gate oxide material 264, the recessed oxide spacer structures 373, and the nitride material 371. After formation of the third conductive structures 374, a planarizing act may be done, such as CMP to achieve a substantially planar upper surface 351 that includes the second stack upper material 250 and the third conductive structures 374 among other exposed structures. Incidental to formation of the third conductive structures 374 and in other regions of the microelectronic device structure 300, contacts may be formed at or near the processing act(s) illustrated, such as in staircase regions (e.g., staircase structures 620, FIG. 6) of the microelectronic device structure 300.

Still referring to FIG. 3X, the channel structures 266, including the doped portion 267 of the channel structures 266, extend vertically along the second insulative material 226 of the second stack tiers 228. The channel structures 266 have a substantially uniform width when seen in cross section and, in three dimensional views, the channel structures 266, including the doped portions 267, have an elongate right cylinder shape. In cross section as illustrated in FIG. 3X, the channel structures 266, including the doped portions 267, have an elongate rectangular shape.

Still referring to FIG. 3X, and referring analogously to FIGS. 2XT and 2Xi, the positioning of the third conductive structures 374 are similarly horizontally offset from a center of corresponding strings of pillar structures 112. In other words, the third conductive structures 374 are aligned with the insulative material 268 but are not aligned with (e.g., are offset from) the symmetry lines 211 of the pillar structures 112. Similar to the thermal annealing process described above for FIG. 2Xi, the top surfaces 267T and the side lateral surfaces 267S of the third conductive structures 374 are converted to a metal silicide (not shown) of the doped portions 267, similar to metal silicide region 267A. The metal silicide forms continuous electrically conductive interfaces between the doped portions 267 of the channel structures 266 and the third conductive structures 374. The metal silicide separates the gate oxide material 264 and the third conductive structures 374, and the portion of the third conductive structures 374 in the second undercut region separates the oxide spacer structures 373 from the doped portions 267 of the channel structures 266. Other features of the microelectronic device structure 300 shown in FIG. 3X may be formed as previously described with respect to FIG. 2X.

FIG. 3Y is a simplified transverse cross section elevation view of the microelectronic device structure 300 illustrated in FIG. 3X after a further processing act has been accomplished according to some embodiments. Replacement-gate processing is accomplished by forming an oxide material 380 on the upper surface 351, patterning the oxide material 380 to form slits (not illustrated) within different regions (not illustrated) of the microelectronic device structure 300, and oxidizing exposed portions of the second stack upper material 250. Thereafter, the replacement-gate process may be conducted similar to that described above in regard to FIG. 2Y. First conductive structures 176 are formed within the first stack structure 110 between vertically adjacent first insulative structures 124, as well as second conductive structures 276 are formed within the second stack structure 210 between vertically adjacent second stack first insulative materials 224. Consequently, tiers 178 are formed within the first stack structure 110 and tiers 278 are formed within the second stack structure 210 that each have first conductive structures 176 and second conductive structures 276, respectively. The second conductive structures 276 of the first stack structure 110 may function as local word line structures (e.g., local or word line plates). Lower portions of the channel structures 266 may be laterally adjacent to lower portions of the second conductive structures 276, and upper portions of the channel structures 266 may be laterally adjacent to upper portions of the second conductive structures 276. The doped portions 267 of the channel structures 266 may be located above uppermost second conductive structures 276. The second conductive structures 276 of the second stack structure 210 may function as select gate structures, such as select gate drain (SGD) structures. Accordingly, the second conductive structures 276 within the upper portions of the second tiers 278 may function as so-called “de-integrated SGDs.” Other features of the microelectronic device structure 300 shown in FIG. 3Y may be formed as previously described with respect to FIG. 2Y.

FIG. 3Z is a simplified transverse cross section elevation view of the microelectronic device structure 300 illustrated in FIG. 3Y after further processing acts have been accomplished according to some embodiments. A masking material 381 has been formed and patterned above the upper surface 351, and at an intersection between two pillar sectors 140, followed by an oxide etch process to remove the oxide material 380 on the upper surface 351. Thereafter, an etch process may be conducted to remove the second stack upper material 250 exposed between the patterned masking material 381, where the etch process is stopped by the second insulative material 325 that is below the second stack upper material 250 and that is above the upper occurrence of the conductive material within the tiers 278. An oxide etch process may subsequently be conducted that further removes materials until exposing an uppermost one of the second conductive structures 276. The second conductive structures 276 may function as word lines after further processing. Other features of the microelectronic device structure 300 shown in FIG. 3Z may be formed as previously described with respect to FIG. 2Z.

FIG. 3AA is a simplified transverse cross section elevation view of the microelectronic device structure 300 illustrated in FIG. 3Z after a further processing act has been accomplished according to some embodiments. Sub-block segmentation may be accomplished at the level of the second stack structure 210 by removing (e.g., etching) materials at the intersection between two pillar sectors 140, forming a sub-block recess 382. The sub-block recess 382 is formed through most of the second tiers 278. The removal of the materials of the second tiers 278 to form the sub-block recess 382 is a self-aligned process where the oxide spacer structures 373 are substantially resistant to the etch chemistries used to achieve directional etching of the second stack first insulative materials 224 and of the second conductive structures 276. The self-aligned directional etching leaves the sub-block recess 382 at the boundaries between two pillar sectors 140. The sub-block recess 382 has different widths along different portions of its length. For instance, portions of the sub-block recess 382 proximal to the interface dielectric structure 138 are narrower than portions of the sub-block recess 382 distal to the interface dielectric structure 138. In other words, the portions of the sub-block recess 382 laterally adjacent to the third conductive structures 374 are wider than the portions of the sub-block recess 382 laterally adjacent to the tiers 278 and insulative material 268 of the second stack structure 210. The microelectronic device structure 300 of FIG. 3AA may be formed as described above for FIG. 2AA. Other features of the microelectronic device structure 300 shown in FIG. 3AA may be formed as previously described with respect to FIG. 2AA.

FIG. 3AB is a simplified transverse cross section elevation view of the microelectronic device structure 300 illustrated in FIG. 3AA after a further processing act has been accomplished according to some embodiments. The masking material 381 may be removed and a wet etch process conducted that selectively removes the second stack upper material 250, while the second conductive structures 276 and the second stack first insulative material 224 of the second tiers 278, and the oxide material 380 remain. Consequently, second stack chambers 384 are formed at an elevation laterally adjacent to an upper portion of the sub-block recess 382 that is self-aligned between third conductive structures 374. Other features of the microelectronic device structure 300 shown in FIG. 3AB may be formed as previously described with respect to FIG. 2AB.

FIG. 3AC is a simplified transverse cross section elevation view of the microelectronic device structure 300 illustrated in FIG. 3AB after a further processing act has been accomplished according to some embodiments. A non-conformal oxide material 386 may be non-conformally formed over the oxide material 380. The non-conformal oxide material 386 may also be formed on sidewalls of the oxide spacer structures 373. Therefore, the non-conformal oxide material 386 is formed partially into the area of the sub-block recess 382 and also bridges over the sub-block recess 382, such that an isolation structure 388 (e.g., including air gap 388) is formed. Put another way, the non-conformal oxide material 386 defines an upper surface of the air gap of the isolation structure 388, and materials of the tiers 278 define sidewalls and a lower surface of the isolation structure 388 between the selected third conductive structures 374. Since the sub-block recess 382 has different widths along different portions of its length, portions of the isolation structure 388 proximal to the interface dielectric structure 138 are narrower than portions of the isolation structure 388 distal to the interface dielectric structure 138. In other words, the portions of the isolation structure 388 laterally adjacent to the third conductive structures 374 are wider than the portions of the isolation structure 388 laterally adjacent to the tiers 278 of the second stack structure 210. Other features of the microelectronic device structure 300 shown in FIG. 3AC may be formed as previously described with respect to FIG. 2AC.

FIG. 3AD is a simplified transverse cross section elevation view of the microelectronic device structure 300 illustrated in FIG. 3AC after a further processing act has been accomplished according to some embodiments. The non-conformal oxide material 386 may be planarized and its height reduced, and a nitride material 390 may be formed over the non-conformal oxide material 386. Thereafter, a masking material (not shown) is patterned, bit line contact openings 392 are formed, and bit line contacts 394 (e.g., conductive contact structures) are formed in the bit line contact openings 392, followed by removing the masking material. The bit line contacts 394 may, for example, be tungsten bit line contacts. The bit line contacts 394 provide electrical communication from the channel structures 266 and the third conductive structures 374 to other conductive structures of the microelectronic device structure 300. The bit line contacts 394 in the bit line contact openings 392 provide the electrical communication to the pillar structures 112 to comprise strings of memory cells within the first stack structure 110. After the replacement-gate act that was carried out as illustrated in part at FIG. 3Y, and in connection with formation of channel structures 266 and the third conductive structures 374, the bit line contacts 394 in the bit line contact openings 392 further completes communication to the pillar structures 112 to comprise strings of memory cells within the first stack structure 110. Other features of the microelectronic device structure 300 shown in FIG. 3AD may be formed as previously described with respect to FIG. 2AD.

Referring again to FIG. 3AD, formation of the third conductive structures 374 within the conductive structure openings 360, where the conductive structure openings 360 are wider than the channel openings 256, allows for increased effectiveness in the doping to form the doped portions 267 of the channel structures 266, which allows for improved lower capacitance issues within the third conductive structures 374, which is useful for signal conveyance between the vertical strings 607 (FIG. 6) of memory cells 603 (FIG. 6) and other structures within a microelectronic device such as a 3D NAND memory device (see FIG. 6).

Referring collectively to FIGS. 2AD and 3AD, the third conductive structures 274 in FIG. 2AD and the third conductive structures 374 in FIG. 3AD differ from one another at least in the additional widened portions 275, 375, 377. These portions of the third conductive structures 274, 374 exhibit a greater width than central portions of the third conductive structures 274, 374. In a cross-sectional view, the third conductive structures 374 have a so-called “T” shape at one end, and an overall so-called “spool” shape when the central and widened portions 375, 377 of the third conductive structures 374 are considered. By contrast, the third conductive structures 274 may have widened portions 275 proximal to the channel structures 266. The third conductive structures 274 may have a smaller target surface onto which bit line contact openings 292 are to be formed, while the third conductive structures 374 may have a larger target surface (the widened portions 375, 377) onto which to form the bit line contact openings 392. The material qualities and the dimensions of the third conductive structures 274, 374 provide low capacitance interconnections between bit lines (not illustrated) and the channel structures 266 including the doped portions 267 of the channel structures 266.

FIG. 4AD is a simplified transverse cross section elevation view of a microelectronic device structure 400, similar to the microelectronic device structure 200 illustrated in FIG. 2AC and having additional structures, where processing has progressed similarly to that achieved in the microelectronic device structure 200 illustrated in FIG. 2AC according to some embodiments. The microelectronic device structure 400 differs, however, from the microelectronic device structure 200 in that top channel plugs 469 may be present and the insulative material 268 completely fills the channel openings 256.

In some embodiments after formation of doped portion 467 of the channel structures 466, the top channel plugs 469 may be formed and also subjected to N⁺ doping implantation at the same time as formation of the doped portions 467 of the channel structures 466. In some embodiments, the top channel plugs 469 are separately formed onto the microelectronic device structure 400. During subsequent processing, metal silicide regions 467A are formed between the third conductive structures 474 and the doped portion 467 of the channel structures 466, and the top channel plugs 469. The top channel plugs 469 may be formed by conventional techniques at appropriate acts during the fabrication process while other features of the microelectronic device structure 400 shown in FIG. 4AD may be formed as previously described with respect to FIGS. 2AD and 3AD.

FIG. 5AD is a simplified transverse cross section elevation view of a microelectronic device structure 500, similar to the microelectronic device structure 300 illustrated in FIG. 3AC and having additional structures, where processing has progressed similarly to that achieved in the microelectronic device structure 300 illustrated in FIG. 3AD according to some embodiments. The microelectronic device structure 500 differs, however, from the microelectronic device structure 300 in that top channel plugs 569 may be present and the insulative material 268 completely fills the channel openings 256.

In some embodiments after formation of doped portions 567 of the channel structures 566, the top channel plugs 569 may be formed and also subjected to N⁺ doping implantation at the same time as formation of the doped portions 567 of the channel structures 566. In some embodiments, the top channel plugs 569 are separately formed. During processing, metal silicide regions 567A are formed between third conductive structures 574 and the doped portions 567 of the channel structures 566, and the top channel plugs 569.

FIG. 6 illustrates a partial cutaway perspective view of a portion of a microelectronic device 600 (e.g., a microelectronic device, a memory device, such as a 3D NAND flash memory device) including a microelectronic device structure 601 that may be one or more microelectronic device structures 200, 300, 400, 500 (e.g., a microelectronic device structure). The microelectronic device 600 may include structures substantially similar to the microelectronic device structures 200, 300, 400, and 500 previously described with reference to the series of FIGS. 1, 2, 3, 4, and 5. As shown in FIG. 6, the microelectronic device structure 601 of the microelectronic device 600 may include a staircase structure 620 defining contact regions for connecting interconnect lines 606 to conductive structures 605 (e.g., corresponding to the second conductive structures 276 (e.g., FIG. 2AD)). The microelectronic device structure 601 may include vertical strings 607 (e.g., corresponding to the pillar structures 112 (FIG. 2AD)) of memory cells 603 that are coupled to each other in series. The vertical strings 607 may extend vertically (e.g., in the Z-direction) and orthogonally to conductive lines and the conductive structures 605, such as data lines 602 (e.g., corresponding to the bit line contacts 294 (FIG. 2AD)), a source tier 604 (e.g., corresponding to the source structure 130 (FIG. 1B)), the conductive structures 605, the interconnect lines 606, first select gates 608 (e.g., upper select gates, drain select gates (SGDs)), such as the second conductive structures 276 (FIG. 2AD) of the second stack structure 210 (FIG. 2AD), select lines 609, and a second select gate 610 (e.g., a lower select gate, a source select gate (SGS)). The first select gates 608 may be horizontally divided (e.g., in the Y-direction) into multiple blocks 632 (e.g., corresponding to the pillar sectors 140 (FIG. 2ADT)) horizontally separated (e.g., in the Y-direction) from one another by filled slot structures 630 (e.g., FIG. 2ADT). As described above, with reference to the microelectronic device 600, the size, shape, and orientation of the isolation structures 288, 388 relative to the channel structures (e.g., 266, 267 FIG. 2AD) and to the third conductive structures 274, 374 (e.g., FIGS. 2AD, 2ADT, 3AD) and the bit line contacts 294, 394 (e.g., FIG. 2AD, FIG. 3AD) may facilitate formation of the first select gates 608 exhibiting relatively improved properties.

Vertical conductive contacts 611 may electrically couple components to each other as shown. For example, the select lines 609 may be electrically coupled to the first select gates 608 and the interconnect lines 606 may be electrically coupled to the conductive structures 605. The microelectronic device 600 may also include a control unit 612 positioned under the memory array, which may include at least one of string driver circuitry, pass gates, circuitry for selecting gates, circuitry for selecting conductive lines (e.g., the data lines 602, the interconnect lines 606), circuitry for amplifying signals, and circuitry for sensing signals. The control unit 612 may be electrically coupled to the data lines 602, the source tier 604, the interconnect lines 606, the first select gates 608, and the second select gates 610, for example. In some embodiments, the control unit 612 includes CMOS (complementary metal-oxide-semiconductor) circuitry. In such embodiments, the control unit 612 may be characterized as having a “CMOS under Array” (“CuA”) configuration.

Still referring to FIG. 6, the first select gates 608 may extend horizontally in a first direction (e.g., the X-direction) and may be coupled to respective first groups of vertical strings 607 of memory cells 603 at a first end (e.g., an upper end) of the vertical strings 607. The second select gate 610 may be formed in a substantially planar configuration and may be coupled to the vertical strings 607 at a second, opposite end (e.g., a lower end) of the vertical strings 607 of memory cells 603.

Still referring to FIG. 6, the data lines 602 (e.g., digit lines, bit lines) may extend horizontally in a second direction (e.g., in the Y-direction) that is at an angle (e.g., perpendicular) to the first direction in which the first select gates 608 extend. Individual data lines 602 may be coupled to individual groups of the vertical strings 607 extending in the second direction (e.g., the Y-direction) at the first end (e.g., the upper end) of the vertical strings 607 of the individual groups. Additional individual groups of the vertical strings 607 extending the first direction (e.g., the X-direction) and coupled to individual first select gates 608 may share a particular vertical string 607 thereof with individual group of vertical strings 607 coupled to an individual data line 602. Thus, an individual vertical string 607 of memory cells 603 may be selected at an intersection of an individual first select gate 608 and an individual data line 602. Accordingly, the first select gates 608 may be used for selecting memory cells 603 of the vertical strings 607 of memory cells 603.

Still referring to FIG. 6, the conductive structures 605 (e.g., word line word lines, such as the second conductive structures 276 (FIG. 2AD)) may extend in respective horizontal planes. The conductive structures 605 may be stacked vertically, such that each conductive structure 605 is coupled to at least some of the vertical strings 607 of memory cells 603, and the vertical strings 607 of the memory cells 603 extend vertically through the stack structure (e.g., the first stack structure 110, FIG. 2AD) including the conductive structures 605. The conductive structures 605 may be coupled to or may form control gates of the memory cells 603.

Still referring to FIG. 6, the first select gates 608 and the second select gates 610 may operate to select a vertical string 607 of the memory cells 603 interposed between data lines 602 and the source tier 604. Thus, an individual memory cell 603 may be selected and electrically coupled to a data line 602 by operation of (e.g., by selecting) the appropriate first select gate 608, second select gate 610, and conductive structure 605 that are coupled to the particular memory cell 603.

Still referring to FIG. 6, the staircase structure 620 may be configured to provide electrical connection between the interconnect lines 606 and the conductive structures 605 through the vertical conductive contacts 611. In other words, an individual conductive structure 605 may be selected via an interconnect line 606 in electrical communication with a respective vertical conductive contact 611 in electrical communication with the conductive structure 605. The data lines 602 (e.g., the bit line contacts 294, 394 FIG. 2AD, FIG. 3AD) may be electrically coupled to the vertical strings 607 through conductive contact structures 634 (e.g., corresponding to the bit line contacts 294, 394 (FIG. 2AD, FIG. 3AD)).

Microelectronic devices (e.g., the microelectronic device 600) including the self-aligned weave pattern of the isolation structures 288, 388 according to embodiments of the disclosure, may be used in embodiments of electronic systems of the disclosure. For example, FIG. 7 is a block diagram of an electronic system 700, in accordance with embodiments of the disclosure. The electronic system 700 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 700 includes at least one memory device 720. The memory device 720 may include, for example, an embodiment of an electronic device (e.g., the microelectronic device 600) previously described with reference to the series of FIGS. 2, 3, 4, 5 and 6 including the self-aligned weave pattern of the isolation structures 288, 388.

The electronic system 700 may further include at least one electronic signal processor device 710 (often referred to as a “microprocessor”). The electronic signal processor device 710 may optionally include an embodiment of an electronic device (e.g., one or more of the microelectronic devices 600 previously described with reference to series of FIGS. 2, 3, 4, 5 and 6). The electronic system 700 may further include one or more input devices 730 for inputting information into the electronic system 700 by a user, such as, for example, a mouse or other pointing device, a keyboard, a touchpad, a button, or a control panel. The electronic system 700 may further include one or more output devices 740 for outputting information (e.g., visual or audio output) to a user such as, for example, a monitor, a display, a printer, an audio output jack, a speaker, etc. In some embodiments, the input device 730 and the output device 740 may comprise a single touchscreen device that can be used both to input information to the electronic system 700 and to output visual information to a user. The input device 730 and the output device 740 may communicate electrically with one or more of the memory device 720 and the electronic signal processor device 710. In some embodiments, the signal processor device 710 and the memory device 720 are part of a disaggregated-die assembly 750 where the signal processor device 710 and the memory device 720 may be interconnected such as with an embedded multi die interconnect bridge (EMIB, not illustrated) and optionally with at least one through-silicon via (TSV) in an integrated circuit package.

Thus, a microelectronic device is disclosed and comprises a first stack structure comprising a vertically alternating sequence of first conductive structures and first insulative structures arranged in first tiers. Strings of memory cells vertically extend through the first stack structure, the strings of memory cells individually comprising a channel material vertically extending through the first stack structure. A second stack structure vertically overlies the first stack structure and comprises a second vertically alternating sequence of second conductive structures and second insulative structures arranged in second tiers. Channel structures extend through the second stack structure and vertically overlie and are electrically coupled to the strings of memory cells. Channel openings contain the channel structures and have a first dimension. Each of the channel structures surrounds an insulative material. Third conductive structures vertically overlie the channel structures, and a metal silicide region of the channel structures electrically connects the channel structures and the third conductive structures. Conductive structure openings contain the third conductive structures and have a second dimension that is larger than the first dimension of the channel openings.

Thus, also disclosed is a method of forming a microelectronic device. The method comprises forming a first stack structure comprising pillar structures, an interface dielectric material adjacent to the first stack structure, a second stack structure comprising channel structures adjacent to the interface dielectric material, an insulative material adjacent to the second stack structure, and a stack material adjacent to the insulative. Portions of the stack material, the insulative material, and the second stack structure are removed to form channel openings exhibiting a first diameter. Additional portions of the stack material are removed to form conductive structure openings above the second stack structure, the conductive structure openings exhibiting a second diameter greater than the first diameter of the channel openings. A portion of the interface dielectric material is removed to form a first undercut region in the interface dielectric material and a portion of the insulative material to form a second undercut region in the second insulative material. Channel structures are formed in the channel openings and oxide spacer structures are formed within the conductive structure openings. Portions of the channel structures laterally adjacent to the insulative material are doped. Conductive structures are formed in the conductive structure openings and adjacent to the oxide spacer structures. Isolation structures comprising air gaps are formed between laterally adjacent conductive structures.

Thus, also disclosed is a memory device that comprises strings of memory cells extending through a first stack structure comprising tiers of alternating first conductive structures and first insulative structures. The strings of memory cells comprise a channel material. A second stack structure comprises tiers of alternating second conductive structures and second insulative structures and is adjacent to the first stack structure. Channel structures are within the second stack structure and contact third conductive structures above the second stack structure. A portion of the third conductive structures proximal to the channel structures exhibit a greater width than a central portion of the third conductive structures. An oxide material overlies the third conductive structures and the oxide material and sidewalls of alternating second conductive structures and second insulative structures define air gaps between laterally adjacent third conductive structures. The air gaps separate the second stack structure into sub-block structures.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A microelectronic device, comprising:
a first stack structure comprising a first vertically alternating sequence of first conductive structures and first insulative materials arranged in first tiers;
strings of memory cells vertically extending through the first stack structure, the strings of memory cells individually comprising a channel material vertically extending through the first stack structure;
a second stack structure vertically overlying the first stack structure and comprising a second vertically alternating sequence of second conductive structures and second insulative materials arranged in second tiers;
channel structures extending through the second stack structure and vertically overlying and electrically coupled to the strings of memory cells, channel openings containing the channel structures having a first dimension, and each of the channel structures surrounding an insulative material; and
third conductive structures vertically overlying the channel structures, wherein a metal silicide region of the channel structures electrically connects the channel structures and the third conductive structures, conductive structure openings containing the third conductive structures having a second dimension that is larger than the first dimension of the channel openings.

2. The microelectronic device of claim 1, wherein the metal silicide region contacts top surfaces and lateral surfaces of the channel structures.

3. The microelectronic device of claim 1, wherein the metal silicide region contacts a doped portion of the channel structures.

4. The microelectronic device of claim 3, wherein the doped portion of the channel structures comprises a portion of a length of the channel structures and a remaining portion of the length of the channel structures is relatively less doped than the doped portion.

5. The microelectronic device of claim 1, wherein a center line of the channel structures is horizontally offset from a center line of a corresponding string of memory cells.

6. The microelectronic device of claim 1, further comprising:
isolation structures laterally adjacent to the third conductive structures and the channel structures and extending into the second stack structure.

7. The microelectronic device of claim 6, wherein slot structures separate the microelectronic device into block structures and the isolation structures separate the block structures into sub-block structures.

8. The microelectronic device of claim 1, wherein a first lateral dimension of the third conductive structures proximal to the channel structures is greater than a second lateral dimension of the third conductive structures distal to the channel structures.

9. The microelectronic device of claim 8, wherein the third conductive structures exhibit a wider portion distal to the channel structures, the wider portion exhibiting a third lateral dimension greater than the second lateral dimension.

10. A method of forming a microelectronic device, comprising:
forming a first stack structure comprising pillar structures, an interface dielectric material adjacent to the first stack structure, a second stack structure comprising channel structures adjacent to the interface dielectric material, an insulative material adjacent to the second stack structure, and a stack material adjacent to the insulative material;
removing portions of the stack material, the insulative material, and the second stack structure to form channel openings exhibiting a first diameter;
removing additional portions of the stack material to form conductive structure openings above the second stack structure, the conductive structure openings exhibiting a second diameter greater than the first diameter of the channel openings;
removing a portion of the interface dielectric material to form a first undercut region in the interface dielectric material;
removing a portion of the insulative material to form a second undercut region in a second insulative material;
forming channel structures in the channel openings;
forming oxide spacer structures within the conductive structure openings;
doping portions of the channel structures laterally adjacent to the insulative material;
forming conductive structures in the conductive structure openings and adjacent to the oxide spacer structures; and
forming isolation structures comprising air gaps between laterally adjacent conductive structures.

11. The method of claim 10, further comprising forming a metal silicide region between the channel structures and the conductive structures.

12. The method of claim 11, wherein forming a metal silicide region between the channel structures and the conductive structures comprises forming the metal silicide region on the doped portions of the channel structures.

13. The method of claim 12, wherein forming the metal silicide region on the doped portions of the channel structures comprises forming the metal silicide region on top surfaces and lateral surfaces of the doped portions of the channel structures.

14. The method of claim 10, wherein removing portions of the stack material, the insulative material, and the second stack structure to form channel openings comprises forming the channel openings laterally offset from a symmetry line of the pillar structures.

15. The method of claim 10, wherein forming isolation structures comprising air gaps between laterally adjacent conductive structures comprises removing a portion of the insulative material and the second stack structure between the laterally adjacent conductive structures and non-conformally forming an oxide material over the laterally adjacent conductive structures.

16. The method of claim 15, wherein forming isolation structures comprising air gaps between laterally adjacent conductive structures comprises forming the air gaps extending from a lower surface of the oxide material and into the second stack structure.

17. The method of claim 15, wherein forming isolation structures comprising air gaps between laterally adjacent conductive structures comprises forming the air gaps exhibiting a larger lateral dimension laterally adjacent to the conductive structures and a smaller lateral dimension laterally adjacent to the second stack structure.

18. The method of claim 10, further comprising forming a metal silicide region in the channel structures, the metal silicide region contacting the conductive structures.

19. A memory device, comprising:
strings of memory cells extending through a first stack structure comprising tiers of alternating first conductive structures and first insulative structures, the strings of memory cells comprising a channel material;
a second stack structure comprising tiers of alternating second conductive structures and second insulative structures adjacent to the first stack structure;
channel structures within the second stack structure and contacting third conductive structures above the second stack structure, a portion of the third conductive structures proximal to the channel structures exhibiting a greater width than a central portion of the third conductive structures; and
an oxide material overlying the third conductive structures, the oxide material and sidewalls of alternating second conductive structures and second insulative structures defining air gaps between laterally adjacent third conductive structures, the air gaps separating the second stack structure into sub-block structures.

20. The memory device of claim 19, wherein the channel structures are laterally offset from a line of symmetry extending through a center of the strings of memory cells.
